(19) United States
(12) Patent Application Publication
(10) Pub. No.: US 2025/0324668 A1
(43) Pub. Date: Oct. 16, 2025

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Hong-Chih CHEN, Changhua County (TW); Fu-Hsiang SU, Zhubei City (TW); Chia-Hao KUO, Taoyuan City (TW); Wen-Li CHIU, Kaohsiung City (TW); Wei-Ju LEE, Kaohsiung City (TW); Jhon-Jhy LIAW, Zhudong Township (TW)

(73) Assignee: Taiwan Semiconductor Manufacturing Company, Ltd., Hsinchu (TW)

(21) Appl. No.: 18/631,979

(22) Filed: Apr. 10, 2024

(51) Int. Cl. H01L 29/423; H01L 29/06; H01L 29/66; H01L 29/775

(52) U.S. Cl. CPC H10D 30/6735; H10D 30/014; H10D 30/43; H10D 62/121; H10D 64/017; H10D 64/018

(57) ABSTRACT

A semiconductor structure includes a substrate, nanostructures, source/drain features, a gate structure, and a dielectric structure. The nanostructures are over the substrate and spaced apart from each other in a Z-direction. The source/drain features are electrically connected to and on opposite sides of the nanostructures in an X-direction. The gate structure extends in a Y-direction and wraps around the nanostructures. The gate structure includes a mortise end portion. The dielectric structure extends in the Y-direction and is in contact with the gate structure in the Y-direction. The dielectric structure includes a tenon end portion matching the mortise end portion of the gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins.

However, as GAA devices continue to be scaled down, conventional methods for manufacturing GAA devices may experience challenges. Accordingly, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, and 2C illustrate circuit schematics of various STD cells that can be implemented in the logic region of the IC chip of FIG. 1 in accordance with some embodiments of the present disclosure.

FIGS. 3 and 4 illustrate circuit schematics of a static random access memory (SRAM) cell that can be implemented in the memory region of the IC chip of FIG. 1, in accordance with some embodiments of the present disclosure.

FIGS. 5, 6, 7, and 14A are perspective views of a workpiece at various fabrication stages, in accordance with some embodiments of the present disclosure.

FIGS. 8A, 9, 10, 11, 12, 13, 16B, 17B, 18B, 19B, and 20B are X-Z cross-sectional views of the workpiece at various fabrication stages along a line A-A′ of FIG. 7, in accordance with some embodiments of the present disclosure.

FIGS. 8B, 14C, 15C, 16C, 17C, 18C, and 19C are Y-Z cross-sectional views of the workpiece at various fabrication stages along a line B-B′ of FIG. 7, in accordance with some embodiments of the present disclosure.

FIGS. 14B and 15B are X-Z cross-sectional views of the workpiece at various fabrication stages along a line C-C′ of FIG. 7, in accordance with some embodiments of the present disclosure.

FIGS. 15A, 16A, 17A, 18A, 19A, and 20A are top views of the workpiece at various fabrication stages, in accordance with some embodiments of the present disclosure.

FIG. 21 is a partial enlarged top view of the workpiece at the fabrication stage in a dashed box of FIG. 20A, in accordance with some embodiments of the present disclosure.

FIG. 22 is a partial enlarged top view of the workpiece at the fabrication stage in the dashed box of FIG. 20A, in accordance with some alternative embodiments of the present disclosure.

FIG. 23 is a partial enlarged top view of the workpiece at the fabrication stage in the dashed box of FIG. 20A, in accordance with some alternative embodiments of the present disclosure.

FIG. 24 is a partial enlarged top view of the workpiece at the fabrication stage in the dashed box of FIG. 20A, in accordance with some alternative embodiments of the present disclosure.

FIG. 25 is a partial enlarged top view of the workpiece at the fabrication stage in the dashed box of FIG. 20A, in accordance with some alternative embodiments of the present disclosure.

FIG. 26 is a Y-Z cross-sectional view of the workpiece at the fabrication stage along the line B-B′ of FIG. 7, in accordance with some alternative embodiments of the present disclosure.

FIG. 27 is a Y-Z cross-sectional view of the workpiece at the fabrication stage along the line B-B′ of FIG. 7, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including a dielectric structure with tenon end portions/jog end portions, such that gate spacers would not be over etched (or damaged) during the formation of the gate structure, thereby improving the performance of the GAA transistors. The details of the structure and manufacturing methods of the present disclosure are described below in conjunction with the accompanying drawings, which illustrate the process of making GAA transistors, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

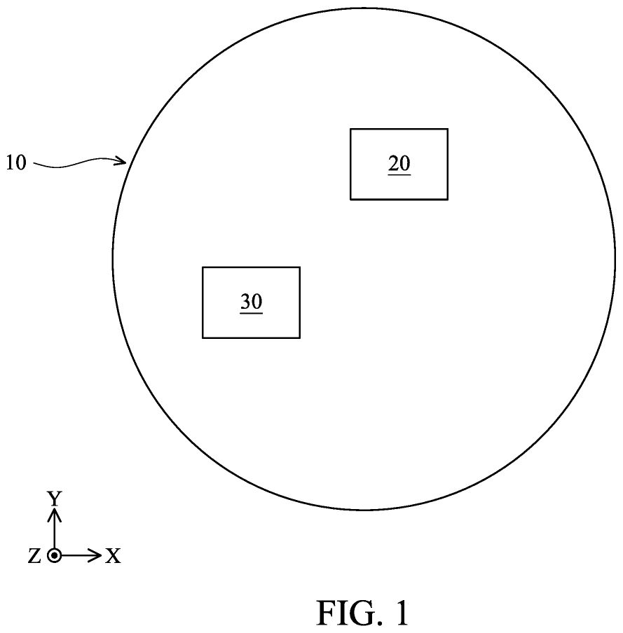

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or a combination thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable memory devices, or combinations thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or combinations thereof.

The logic region 30 can include an array of circuit cells having various logic cells or standard (STD) cells. The logic cells or STD cells may include transistors and interconnection structures that combine to provide a logic device and/or a logic function, such as an inverter, an AND, an NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

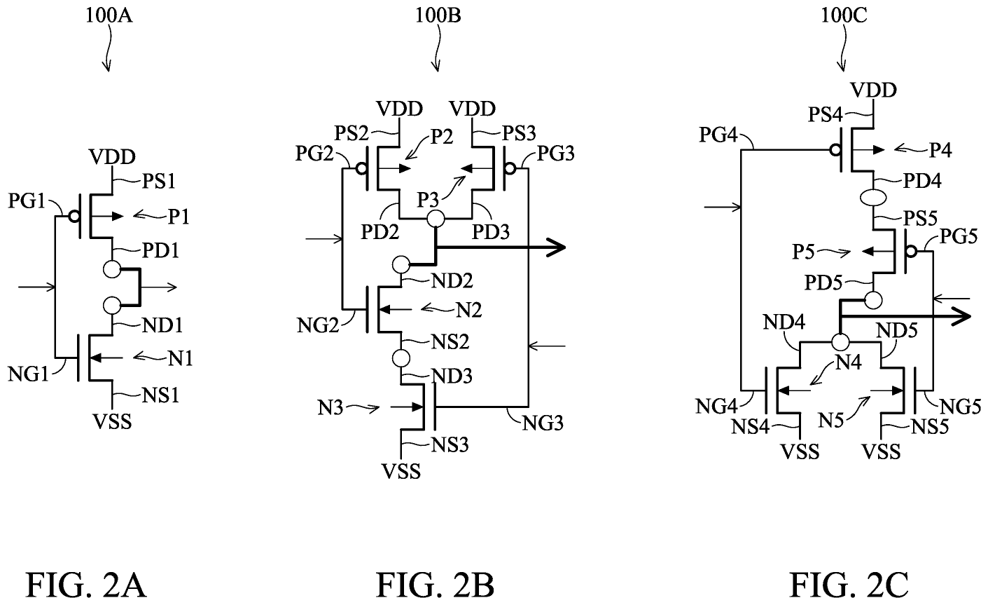

FIGS. 2A to 2E are circuit schematics of various STD cells in the array of circuit cells in the logic region 30 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

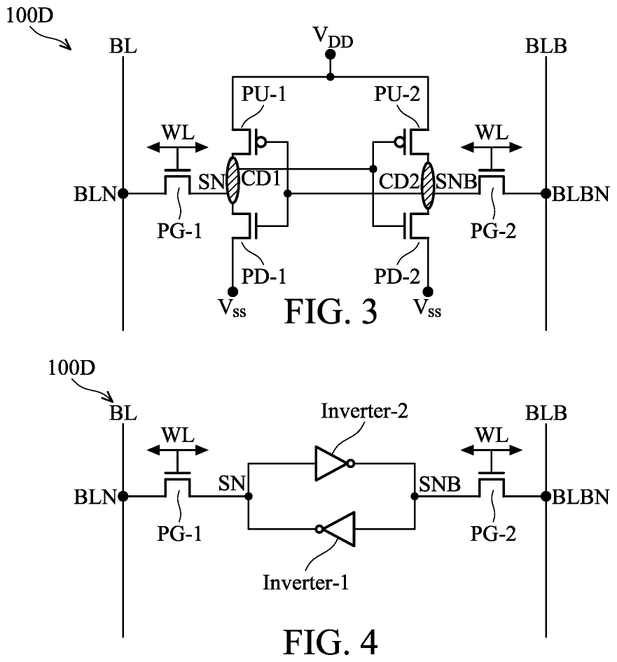

FIGS. 3 and 4 are circuit diagrams of an SRAM circuit that can be implemented in an SRAM cell of an array in the memory region 20 of FIG. 1, in accordance with some embodiments of the present disclosure. The circuit diagram of SRAM cell is merely exemplary, and in some embodiments, each of SRAM cells in the array is configured with an SRAM circuit similar to the SRAM cells 100D as shown in FIGS. 2 and 3. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inverter-2, and pass-gate transistor PG-2 is connected to an output of Inverter-2 and an input of Inverter-1.

In operation, pass-gate transistor PG-1 and pass-gate transistor PG-2 provide access to the storage portion of their respective SRAM cell (i.e., Inverter-1 and Inverter-2) and can also be referred to as access transistors of their respective SRAM cell. Each of SRAM cells is connected to and powered through a first power supply voltage, such as a positive power supply voltage, and a second power supply voltage, such as a ground voltage or a reference voltage (which can be an electrical ground).

A gate of pull-up transistor PU-1 interposes a source, which is electrically coupled to the first power supply voltage via a voltage node (or voltage source) V_{DD}, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) V_{SS}, and the first common drain.

A gate of pull-up transistor PU-2 interposes a source, which is electrically coupled to the first power supply voltage via voltage node V_{DD}, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node V_{SS}, and the second common drain.

The first common drain provides a storage node SN that stores data in true form, and the second common drain provides a storage node SNB that stores data in complementary form, or vice versa, in some embodiments. The gate of pull-up transistor PU1 and the gate of pull-down transistor PD-1 are coupled together and to the second common drain SD2, and the gate of pull-up transistor PU-2 and the gate of pull-down transistor PD-2 are coupled together and to the first common drain SD1.

A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2.

Gates of pass-gate transistors PG-1, PG-2 are connected to and controlled by a word line WL, which allows selection of a respective SRAM cell for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to the gates of the pass-gate transistors PG-1, PG-2 by the word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs.

FIGS. 3 and 4 have been simplified for the sake of clarity to better understand the inventive concepts of the present disclosure. Additional features can be added in the SRAM circuits of FIGS. 3 and 4, and some of the features described herein can be replaced, modified, or eliminated in other embodiments of the SRAM circuits of FIGS. 3 and 4.

Each of the circuit cells and the SRAM cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, exemplary GAA transistors for the circuit cells and the SRAM cells discussed above are illustrated and described below. More specifically, the manufacturing method and the structure of GAA transistors with improved dielectric layer between nanostructures and substrate for the circuit cells and the SRAM cells discussed above are illustrated and described below. However, it should be understood that the application should not be limited to a particular type of device, except as specifically claimed.

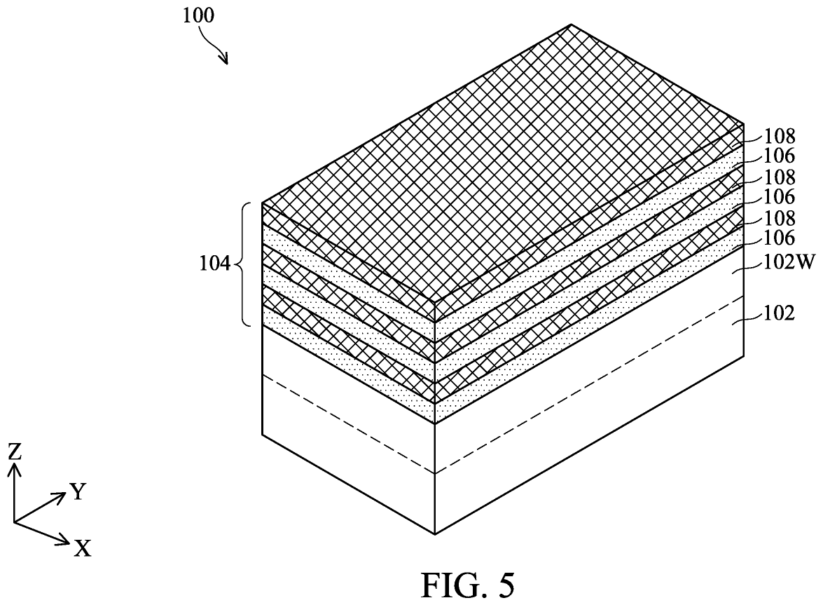

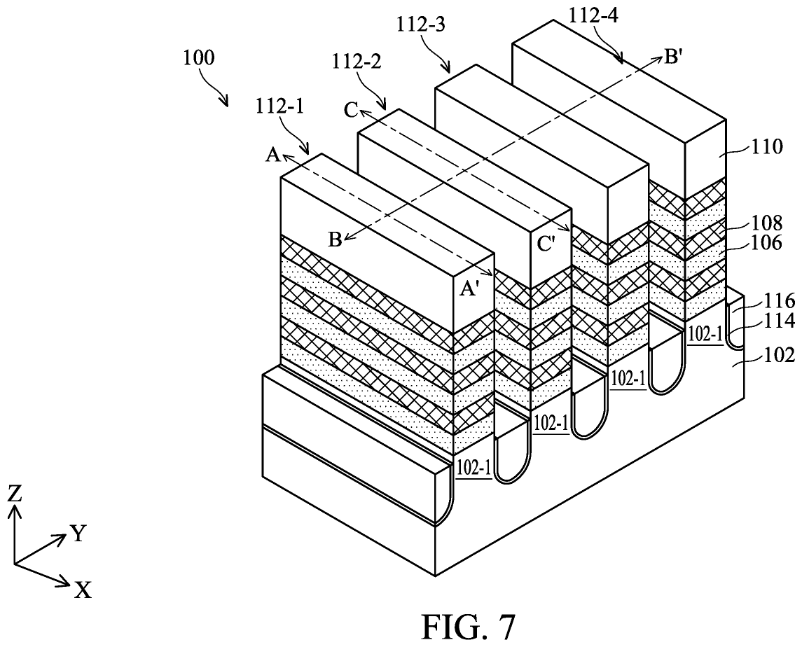

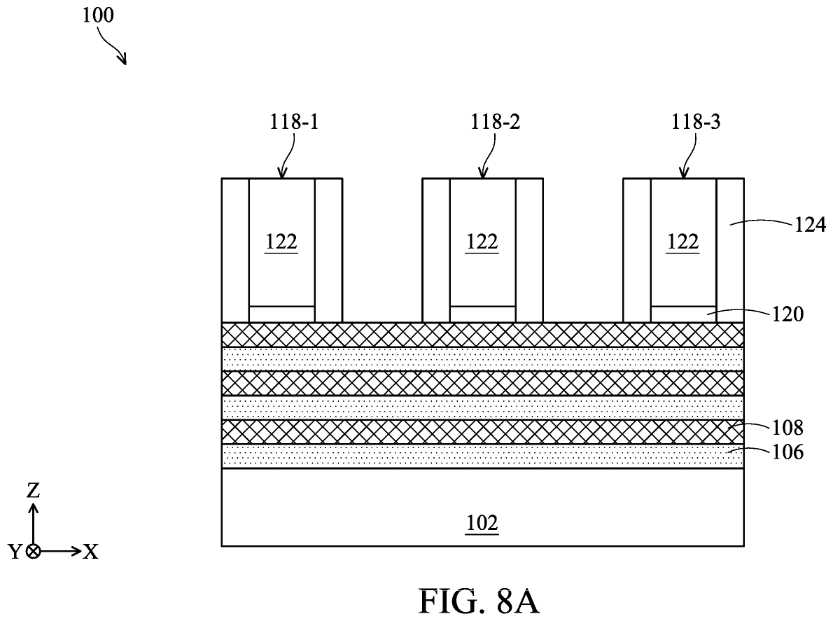

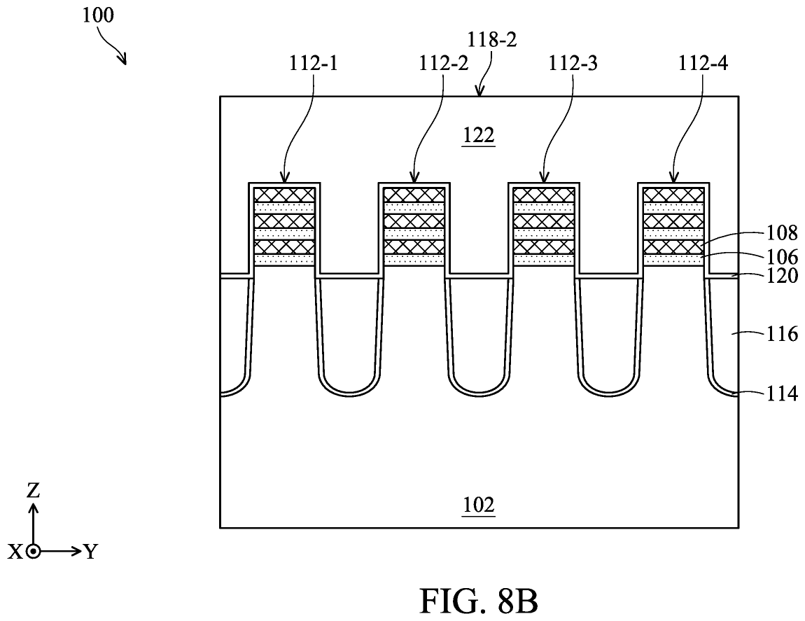

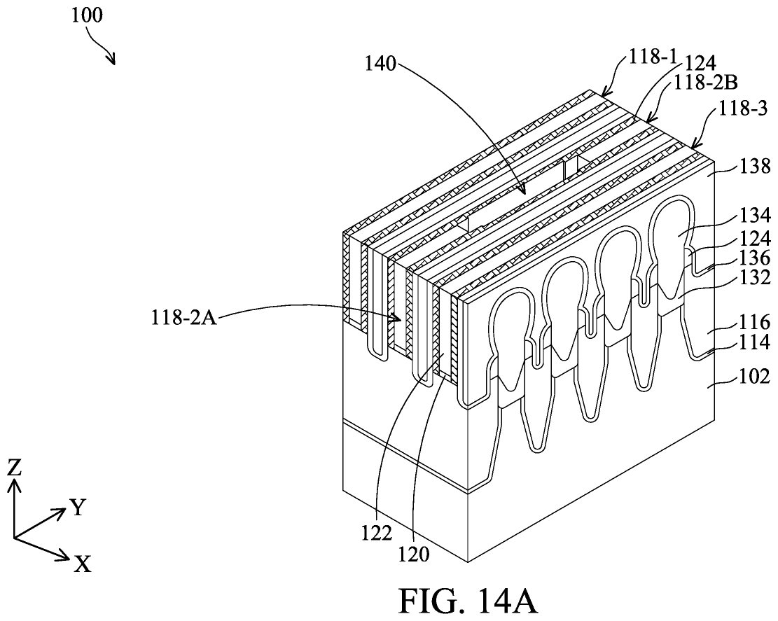

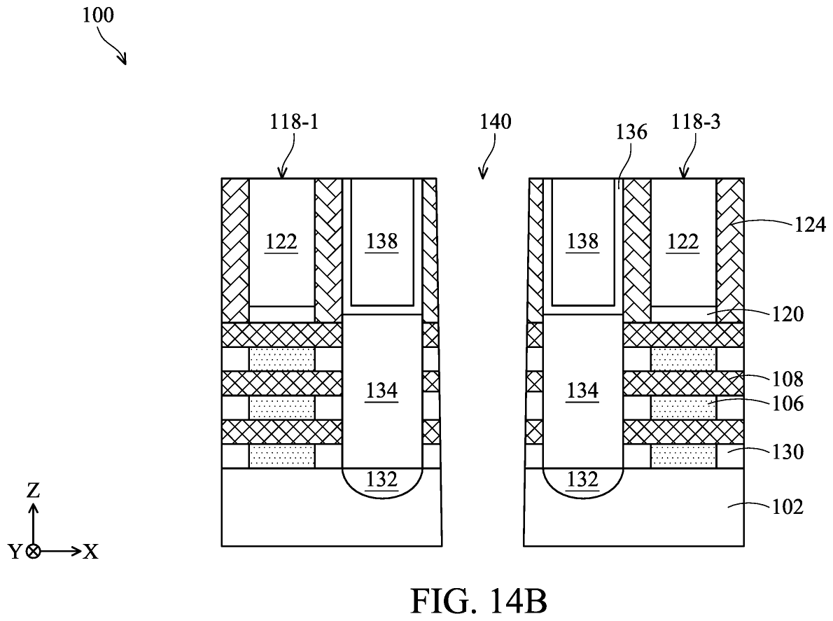

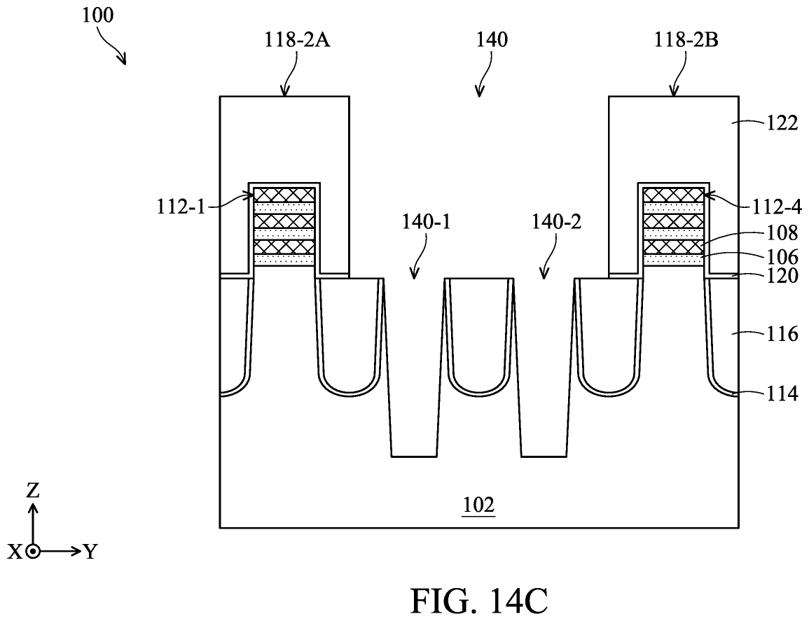

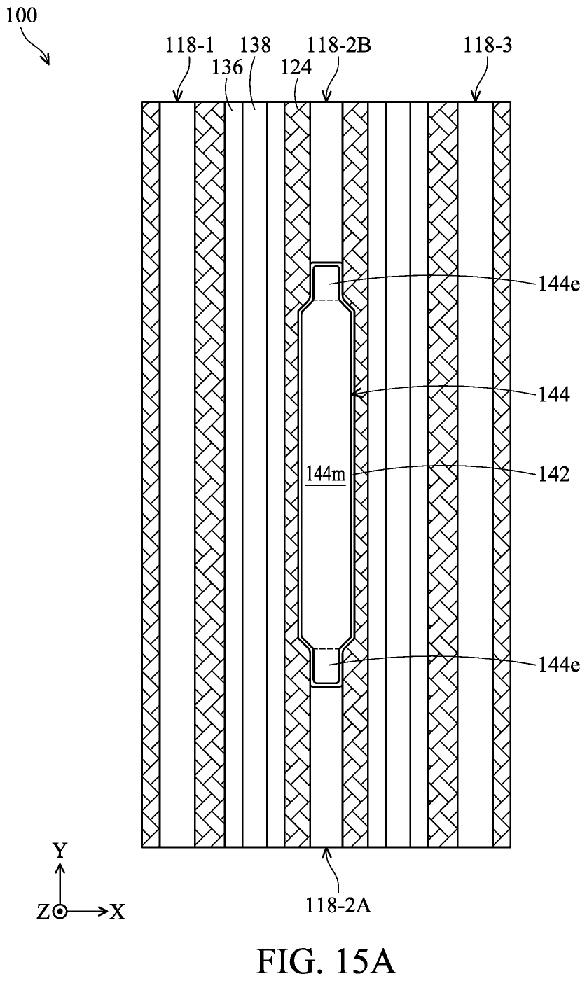

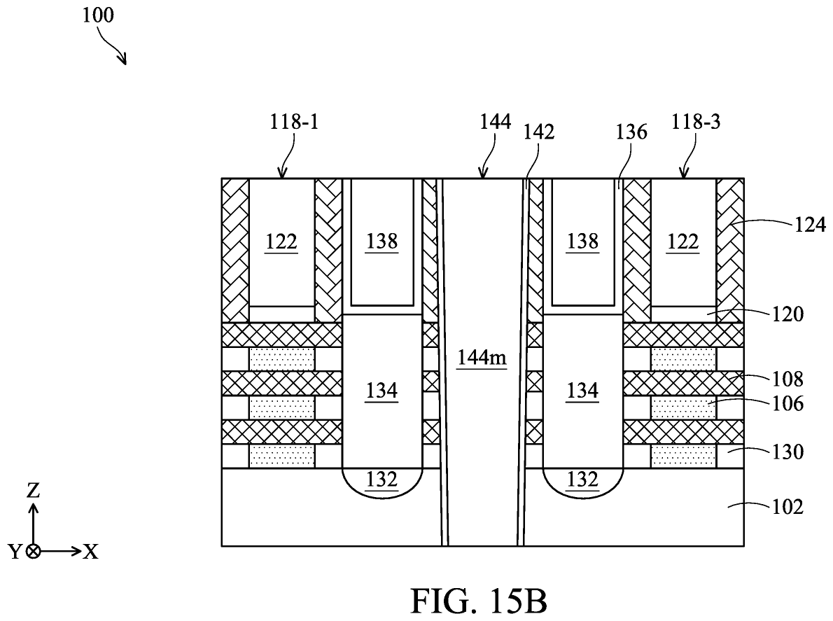

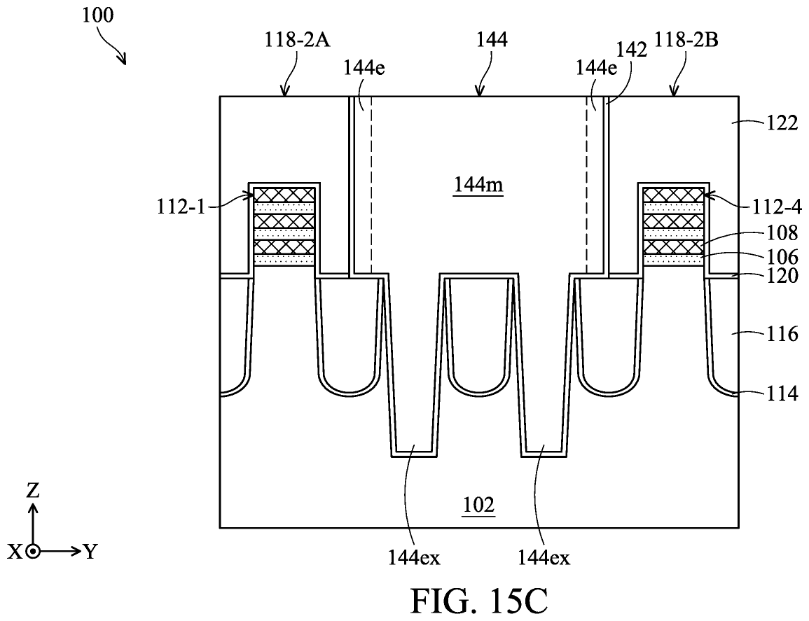

FIGS. 5, 6, 7, and 14A are perspective views of a workpiece 100 at various fabrication stages, in accordance with some embodiments of the present disclosure. FIGS. 8A, 9, 10, 11, 12, 13, 16B, 17B, 18B, 19B, and 20B are X-Z cross-sectional views of the workpiece 100 at various fabrication stages along a line A-A′ of FIG. 7, in accordance with some embodiments of the present disclosure. FIGS. 8B, 14C, 15C, 16C, 17C, 18C, 19C, and 18B are Y-Z cross-sectional views of the workpiece 100 at various fabrication stages along a line B-B′ of FIG. 7, in accordance with some embodiments of the present disclosure. FIGS. 14B and 15B are X-Z cross-sectional views of the workpiece 100 at various fabrication stages along a line C-C′ of FIG. 7, in accordance with some embodiments of the present disclosure. FIGS. 15A, 16A, 17A, 18A, 19A, and 20A are top views of the workpiece 100 at various fabrication stages, in accordance with some embodiments of the present disclosure.

Referring to FIG. 5, the workpiece 100 is provided. The workpiece 100 may include a substrate 102 and a stack 104 over the substrate 102. In some embodiments, the substrate 102 contains a semiconductor material, such as bulk silicon (Si). Alternatively or additionally, in some other embodiments, another elementary semiconductor, such as germanium (Ge) in a crystalline structure, may also be included in the substrate 102. The substrate 102 may also include a compound semiconductor, such as silicon germanium (SiGe) or a III-V semiconductor material. Example III-V semiconductor materials may include silicon carbide (SiC), indium arsenide (InAs), indium antimonide (InSb), indium phosphide (InP), gallium arsenide (GaAs), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and/or indium gallium arsenide (InGaAs), or combinations thereof. The substrate 102 may also include an insulating layer, such as a silicon oxide layer, to have a semiconductor-on-insulator substrate, such as Si-on-insulator (SOI), SiGe-on-insulator (SGOI), Ge-on-insulator (GOI) substrates.

In some embodiments, the substrate 102 may include various doped regions configured according to design requirements of GAA transistors. In some embodiments, the substrate 102 may include a doped region 102W (also referred to as a well region). The doped region 102W may be an n-type doped region (also referred to as an n-well) or a p-type doped region (also referred to as a p-well), and the n-type doped region is configured for a p-type metal-oxide-semiconductor (PMOS) transistor and the p-type doped region is configured for an n-type MOS (NMOS) transistor. N-type doped region is doped with n-type dopants, such as phosphorus, arsenic, other n-type dopant, or combinations thereof. P-type doped region is doped with p-type dopants, such as boron (for example, BF₂), indium, other p-type dopant, or combinations thereof.

In the present embodiment, the substrate 102 shows one doped region 102W. In other embodiments, substrate 102 may include multiple doped regions formed with a combination of p-type dopants and n-type dopants. An ion implantation process, a diffusion process, and/or other suitable doping process can be performed to form the various doped regions. In some embodiments, n-type doped region has an n-type dopant concentration of about 5×10¹⁶ cm⁻³ to about 5×10¹⁹ cm⁻³, and p-type doped region has a p-type dopant concentration of about 5×10¹⁶ cm⁻³ to about 5×10¹⁹ cm⁻³. Because the workpiece 100 will be fabricated into a semiconductor structure 100 upon conclusion of the fabrication processes, the workpiece 100 may be referred to as the semiconductor structure 100 as the context requires.

The stack 104 includes semiconductor layers 106 and 108, and the semiconductor layers 106 and 108 are alternatingly stacked in the Z-direction. The semiconductor layers 106 and the semiconductor layers 108 may have different semiconductor compositions. In some embodiments, semiconductor layers 106 are formed of silicon germanium (SiGe) and the semiconductor layers 108 are formed of silicon (Si). In these embodiments, the additional germanium content in the semiconductor layers 106 allow selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 106 and the semiconductor layers 108 are deposited alternatingly, one-after-another, to form the stack 104.

It should be noted that three (3) layers of the semiconductor layers 106 and three (3) layers of the semiconductor layers 108 are alternately and vertically arranged (or stacked) as shown in FIG. 5, which are for illustrative purposes only and not intended to be limiting beyond what is specifically recited in the claims. The number of layers depends on the desired number of channel members for the semiconductor device. In some embodiments, there may be from 2 to 10 semiconductor layers 106 alternating with 2 to 10 semiconductor layers 108 in the stack 104.

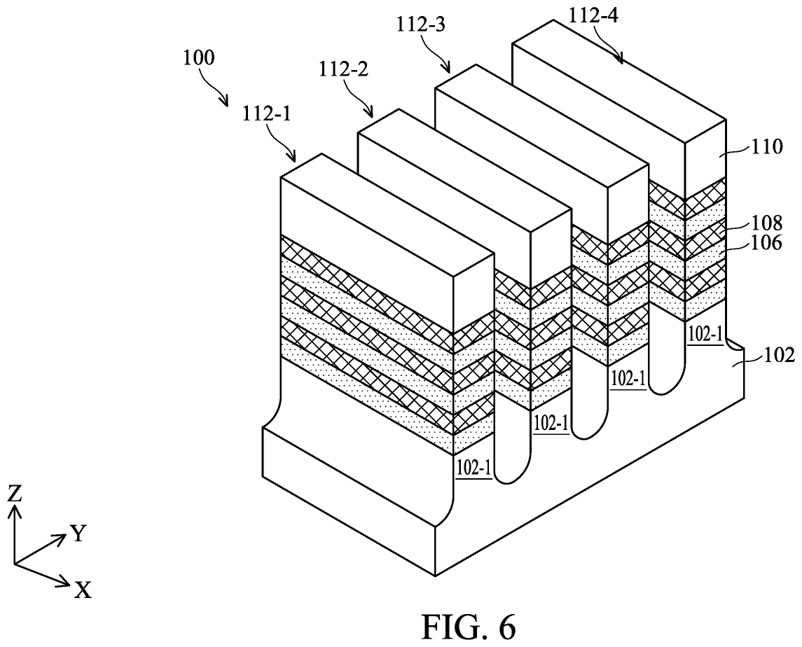

Referring to FIG. 6, the substrate 102 and the stack 104 are then patterned to form a fins 112-1 to 112-4 (may be collectively referred to as fins 112) over the substrate 102. For patterning purposes, the workpiece 100 may also include a hard mask layer 110 over the stack 104 before the patterning of the substrate 102 and the stack 104. The hard mask layer 110 may be a single layer or a multi-layer. In some embodiments, the hard mask layer 110 is a single layer and includes a silicon germanium layer. In some embodiments, the hard mask layer 110 is a multi-layer and includes a silicon nitride layer and a silicon oxide layer over the silicon nitride layer. In some other embodiments, the hard mask layer 110 is a multi-layer and includes a silicon germanium layer and a silicon layer over the silicon germanium layer.

As shown in FIG. 6, each of the fins 112 includes a base fin 102-1 formed from a portion of the substrate 102 and a stack portion formed from the stack 104 over the base portion. In some aspects, the base fins 102-1 protrude from the substrate 102. Each of the fins 112 may include the semiconductor layers 106 and 108 alternating stacked in the Z-direction. The fins 112 extend lengthwise (e.g., longitudinally) in the X-direction, as shown in FIG. 6. Although four fins 112 are formed and shown herein, less or more fins may be formed, such as two or more fins.

The fins 112 may be patterned using suitable processes including double-patterning or multi-patterning processes. For example, in some embodiments, a material layer of the hard mask layer 110 is formed over the substrate 102 and patterned into the hard mask layer 110 using a photolithography process. One or more etching processes are then performed to etch the stack 104 and top portions of the substrate 102 not covered by the hard mask layer 110 to form the fins 112. The etching process may include dry etching, wet etching, reactive ion etching (RIE), and/or other suitable processes.

Referring to FIG. 7, isolation features 116 are formed over the substrate 102. More specifically, after the fins 112 are formed, the hard mask layer 110 over the fins 112 is removed and the isolation features 116 are then formed over the substrate 102. In some aspects, the isolation features 116 are formed around the fins 112. More specifically, the isolation features 116 are formed on opposite sides of the fins 112 (semiconductor layers 106 and 108) in the Y-direction. The isolation features 116 may be shallow trench isolation (STI) features that provide electrical isolation between the different GAA transistors, in accordance with some embodiments. As such, the isolation features 116 may also be referred to as STI features.

In some embodiments, a dielectric material for the isolation features 116 are first deposited over the workpiece 100. Specifically, the dielectric material is deposited and formed over the fins 112 and the substrate 102 to cover the fins 112 and the substrate 102. In some aspects, the dielectric material is formed to wrap around the fins 112. In some embodiments, the dielectric material may include silicon oxide, silicon nitride, silicon oxynitride, silicon carbide, borosilicate glass (BSG), phosphoric silicate glass (PSG), borophosphosilicate glass (BPSG), fluorine-doped silicate glass (FSG), a low-k dielectric (e.g., a carbon doped oxide, SiCOH), combinations thereof, and/or other suitable materials. In various embodiments, the dielectric material may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material is then thinned and planarized, for example by a chemical mechanical polishing (CMP) process. The planarized dielectric material is further recessed by a dry etching process, a wet etching process, and/or a combination thereof to form the isolation features 116.

In some embodiments, the isolation features 116 may have a multi-layer structure such as a thermal oxide liner layer over the substrate 102 and a filling layer (e.g., silicon nitride or silicon oxide) over the thermal oxide liner layer. In some embodiments, before the formation of the isolation features 116, a liner layer 114 may be conformally deposited over the substrate 102 using ALD or CVD. Furthermore, as shown in FIG. 7, the stack portions of the fins 112 rise above the isolation features 116 while the base fin 102-1 are surrounded by the isolation features 116. In some embodiments, top surfaces (or topmost surfaces) of the substrate 102 is higher than top surfaces of the isolation features 116. In other words, the top surfaces of the isolation features 116 are lower than the top surfaces (or the topmost surfaces) of the substrate 102.

Referring to FIGS. 8A and 8B, dummy gate structures 118-1 to 118-3 (may be collectively referred to as dummy gate structures 118) may be formed over the fins 112, the isolation feature 116, and the substrate 102. The dummy gate structures 118 may be configured to extend lengthwise in the Y-direction and wrap around top surfaces and side surfaces of the fins 112, as shown in FIG. 8B. In some embodiments, to form the dummy gate structures 118, a dummy interfacial material of a dummy interfacial layer 120 is first formed over fin 112 and over the isolation feature 116. In some embodiments, the dummy interfacial layer 120 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 122 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., PVD, CVD, PECVD, and ALD).

In some embodiments, hard mask layers may be formed over the dummy gate material. In some embodiments, the hard mask layers may be formed using photolithography and removal (e.g., etching) processes. In some embodiments, the hard mask layers may include photoresist materials or hard mask materials. In some embodiments, each of the hard mask layers may include multiple layers, such as a silicon nitride layer and a silicon oxide layer. After the formation of the hard mask layers, a removal process (e.g., etching) may be performed to remove portions of the dummy gate material for the dummy gate electrodes 122 that do not directly underlie the hard mask layers, thereby forming the dummy gate structures 118 each having the dummy interfacial layer 120, the dummy gate electrode 122, and the hard mask layer. The dummy interfacial layers 120 may also be referred to as dummy gate dielectrics. The dummy gate structures 118 may undergo a gate replacement process through subsequent processing to form metal gates, such as a high-k metal gate, as discussed in greater detail below.

FIG. 8A shows three dummy gate structures 118-1 to 118-3. In some embodiments, less or more dummy gate structures may be formed for one or more transistors sharing source/drain regions. In other embodiments, some dummy gate structures may also undergo a gate replacement process to form dielectric based gates that electrically isolate transistors formed by the dummy gate structure 118 from neighboring transistors or devices. For examples, dummy gate structures 118-1 and 118-3 may be replaced with dielectric material in sequent processes to form dielectric based gates to isolate resultant transistor formed from the dummy gate structure 118-2 from neighboring transistors or devices.

Still referring to FIGS. 8A and 8B, after the formation of the dummy gate structures 118, the hard mask layers are removed and gate spacers 124 are formed on the sidewalls of the dummy gate structures 118, over top surfaces of the fins 112, and on sidewalls of the fins 112 (not shown). More specifically, the gate spacers 124 are formed on opposite sidewalls of the fins 112 (not shown) and formed on opposite sidewalls of the dummy gate structures 118, as shown in FIG. 8A. The gate spacers 124 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 124 may include a single layer or a multi-layer structure. In some embodiments, the gate spacers 124 may be formed by conformally depositing a spacer layer (containing the dielectric material) over the isolation features 116, the fins 112, and dummy gate structures 118, followed by an anisotropic etching process to remove top portions of the spacer layer from the top surfaces of the isolation features 116, the fins 112, and dummy gate structures 118. After the etching process, portions of the spacer layer on the sidewall surfaces of the fins 112 (not shown) and the dummy gate structures 118 substantially remain and become the gate spacers 124. In some embodiments, the anisotropic etching process is a dry (e.g., plasma) etching process. Additionally or alternatively, the formation of the gate spacers 124 may also involve chemical oxidation, thermal oxidation, ALD, CVD, and/or other suitable methods. The gate spacers 124 may also be interchangeably referred to as the top spacers.

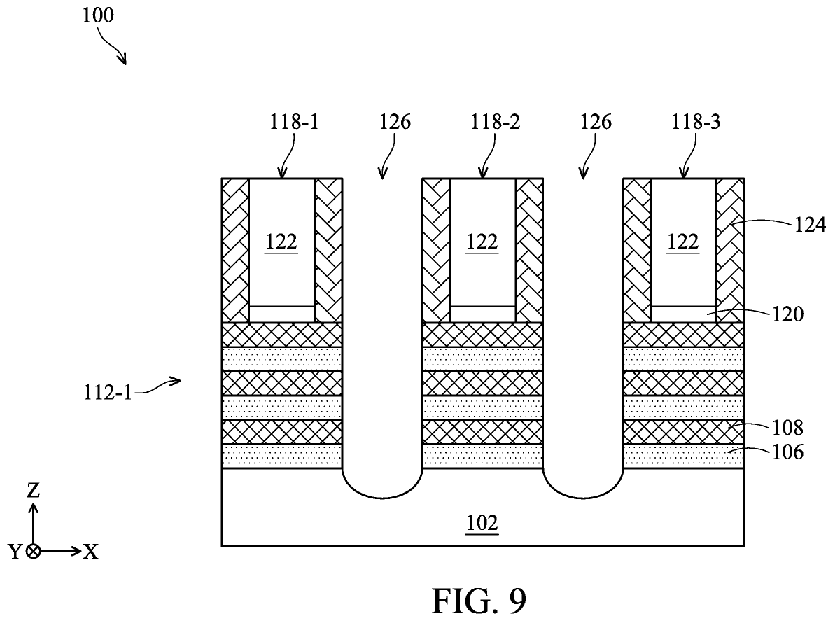

Referring to FIG. 9, the fins 112 are recessed to form source/drain trenches 126 in the fins 112 (or passing through the semiconductor layers 106 and 108) exposed by the dummy gate structures 118. More specifically, the source/drain trenches 126 may be formed by performing one or more etching processes to remove portions of the semiconductor layers 106, the semiconductor layers 108, and the substrate 102 that do not vertically overlap or be covered by the dummy gate structures 118 and gate spacers 124. In some embodiments, a single etchant may be used to remove the semiconductor layers 106, the semiconductor layers 108, and the substrate 102, whereas in other embodiments, multiple etchants may be used to perform the etching process. As shown in FIG. 9, portions of the substrate 102 are etched so that the substrate 102 has concave surfaces, and the concave surfaces are lower than the top surfaces of the isolation features 116 (not shown).

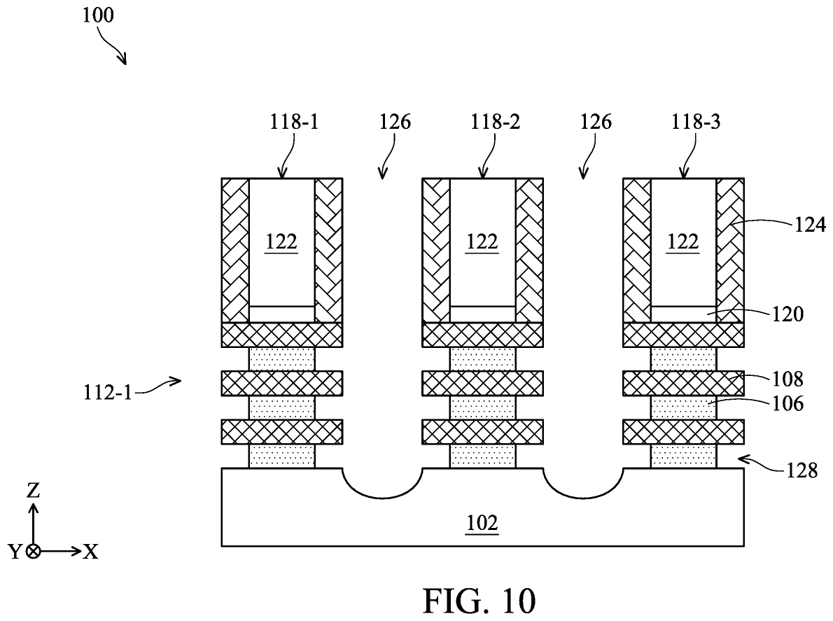

Referring to FIG. 10, side portions of the semiconductor layers 106 are removed via a selective etching process. More specifically, the selective etching process is performed that selectively etches the side portions of the semiconductor layers 106 below the gate spacers 124 through the source/drain trenches 126, with minimal (or no) etching of semiconductor layers 108, the gate spacers 124, and the substrate 102, such that gaps 128 are formed vertically between (the side portions of) the semiconductor layers 108 in the Z-direction as well as vertically between (the side portions of) the semiconductor layers 108 and the substrate 102 in the Z-direction, and below the gate spacers 124. The etching process is configured to laterally etch (e.g., along the X-direction) the semiconductor layers 106 below the gate spacers 124. The selective etching process is a dry etching process, a wet etching process, other suitable etching process, or combinations thereof.

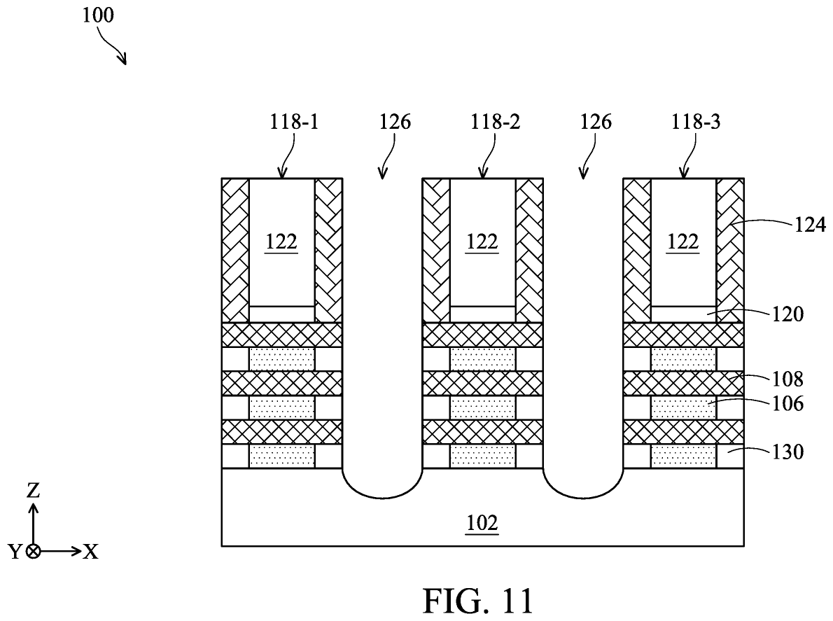

Referring to FIG. 11, inner spacers 130 are formed to fill the gaps 128. The inner spacers 130 are between the semiconductor layers 108 and between the (bottommost) semiconductor layers 108 and the substrate 102 direct under the gate spacers 124. In some embodiments, sidewalls of the inner spacers 130 are aligned to the sidewalls of the gate spacers 124 and the semiconductor layers 108, as shown in FIG. 11. In order to form the inner spacers 130, a deposition process forms a spacer layer into the source/drain trenches 126 and the gaps 128, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 126. The deposition process is configured to ensure that the spacer layer fills the gaps 128 between the semiconductor layers 108 as well as between the semiconductor layer 108 and the substrate 102 under the gate spacers 124. An etching process is then performed that selectively etches the spacer layer to form inner spacers 130 (as shown in FIG. 11) with minimal (to no) etching of the semiconductor layer 108, the substrate 102, the dummy gate structure 118, and the gate spacers 124.

The spacer layer (and thus inner spacers 130) includes a material that is different than a material of the semiconductor layers 108 and a material of the gate spacers 124 to achieve desired etching selectivity during the etching process. In some embodiments, the inner spacers 130 include a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)). In some embodiments, the inner spacers 130 include a low-k dielectric material, such as those described herein.

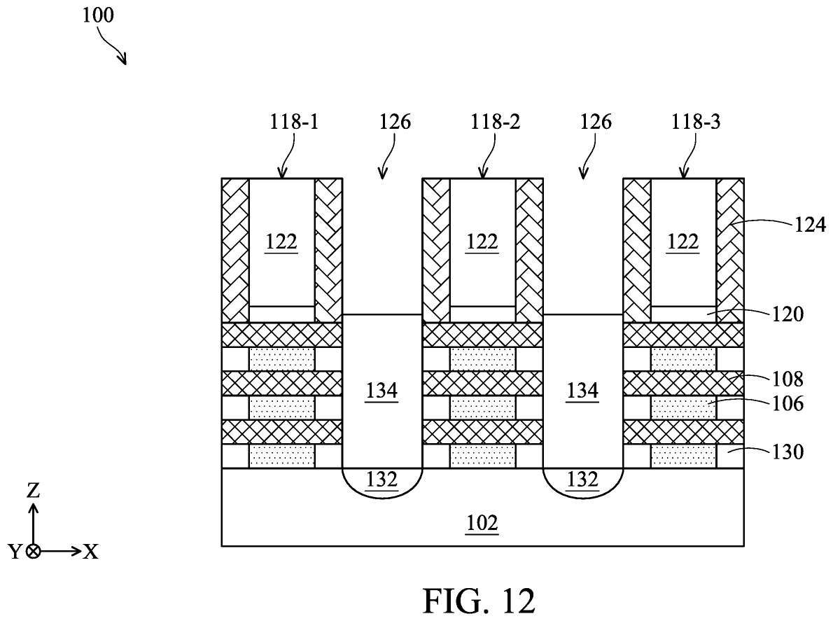

Referring to FIG. 12, silicon layers 132 are formed over the substrate 102 in the source/drain trenches 126. As shown in FIG. 12, the silicon layers 132 are also formed on opposite sides of the dummy gate structures 118, the semiconductor layers 108, and the semiconductor layers 106. In some embodiment, top surfaces of the silicon layers 132 are substantially level with the top surfaces of the substrate 102 and the bottommost surfaces of the semiconductor layers 106 (more specifically, the bottommost semiconductor layer 106), in the X-Z cross-sectional view, as shown in FIG. 12. In some embodiments, the top surfaces of the silicon layers 132 are lower than bottommost surfaces of the semiconductors 106. In some embodiment, the silicon layers 132 each has a convex bottom surface due to the concave surfaces of the substrate 102 in the source/drain trenches 126 discussed above.

The silicon layers 132 are made of silicon without dopants. In other word, the silicon layers 132 are un-doped silicon, and thus may be referred to as un-doped silicon layers. As such, the leakage current of the resultant transistors from one source/drain feature to another source/drain feature through the substrate 102 is prevented, thereby improving performances of the resultant transistors. One or more epitaxy processes may be performed to form the silicon layers 132. Epitaxy processes may implement CVD deposition techniques (for example, vapor-phase epitaxy (VPE), UHVCVD, LPCVD, and/or PECVD), molecular beam epitaxy, other suitable SEG processes, or combinations thereof.

Still referring to FIG. 12, source/drain features 134 are formed in the source/drain trenches 126 and over the silicon layers 132 and the substrate 102, so that the source/drain features 134 pass through the semiconductor layers 108 and are in the fins 112. The source/drain features 134 are also formed on opposite sides of the dummy gate structures 118 in the X-direction. For example, the source/drain features 134 are formed on opposite sides of the dummy gate structure 118-2 in the X-direction, as shown in FIG. 12. Furthermore, the source/drain features 134 are disposed on opposite sides of the semiconductor layers 108 in the X-direction. The source/drain features 134 are connected to and in contact with the semiconductor layers 108. More specifically, the source/drain features 134 are attached and electrically connected to the semiconductor layers 108 in the X-direction. As shown in FIG. 12, the source/drain features 134 are also in contact with the inner spacers 130, but are electrically isolated from the inner spacers 130. In some aspects, the inner spacers 130 are disposed between the source/drain features 134 and the dummy gate structures 118 in the X-direction. Furthermore, the silicon layers 132 are between the source/drain features 134 and the substrate 102 in the Z-direction. In some aspect, the silicon layers 132 are under the source/drain features 134 and over the substrate 102. More specifically, the silicon layers 132 are vertically between and in contact with the source/drain features 134 and the substrate 102 in the Z-direction.

In some aspects, the semiconductor layers 108 serve as channels to connect one source/drain feature 134 to the other source/drain feature 134. Therefore, the semiconductor layers 108 may also be referred to as channels, channel layers, or channel members. In some embodiments, in the X-Z cross-sectional view shown in FIG. 12, the source/drain features 134 may have top surfaces that extend higher than top surfaces of the topmost semiconductor layers 108 (e.g., in the Z-direction), as shown in FIG. 12. In some embodiments, in the X-Z cross-sectional view shown in FIG. 12, the source/drain features 134 may have the top surfaces that extend higher than bottom surfaces of the dummy interfacial layers 120 (e.g., in the Z-direction). In other embodiments, the top surfaces of the source/drain features 134 are substantially level with the top surfaces of the topmost semiconductor layers 108 (i.e., substantially coplanar).

One or more epitaxy processes may be employed to grow the source/drain features 134. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 134 may include any suitable semiconductor materials. For example, the source/drain features 134 used for n-type GAA transistors may include epitaxially-grown material selected from a group consisting of silicon phosphide (SiP), silicon carbide (SiC), silicon phosphoric carbide (SiPC), silicon arsenide (SiAs), silicon (Si), or a combination thereof. In some embodiments, the epitaxially-grown material of the source/drain features 134 may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 134 for n-type GAA transistors may respectively be referred to as n-type source/drain features.

The source/drain features 134 used for p-type GAA transistors may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 134 may be doped with p-type dopants (such as boron, indium, other p-type dopant, or a combination thereof) having a doping concentration in a range from about 1×10¹⁹/cm³ to 6×10²⁰/cm³. In some embodiments, the source/drain features 134 for p-type GAA transistors may respectively be referred to as p-type source/drain features.

The source/drain features 134 may also be referred to as source/drain, or source/drain regions. In some embodiments, source/drain feature(s) 134 may refer to a source or a drain, individually or collectively dependent upon the context. The source/drain features 134 may be doped in-situ or ex-situ. One or more annealing processes may be performed to activate the dopants in the source/drain features 134. The annealing processes may include rapid thermal annealing (RTA) and/or laser annealing processes.

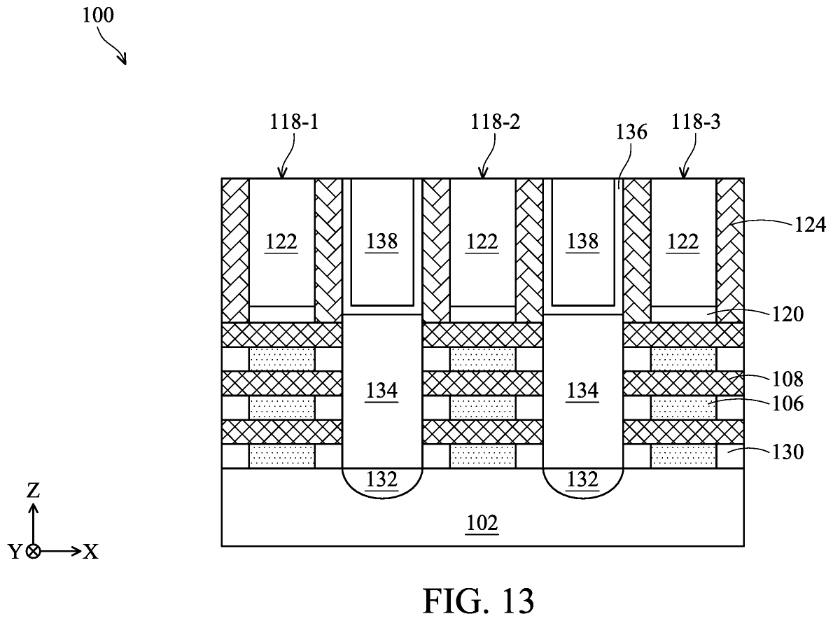

Referring to FIG. 13, a contact etch stop layer (CESL) 136 over the source/drain features 134 and an interlayer dielectric (ILD) layer 138 over the CESL 136 are formed to fill the spaces between the gate spacers 124 and in the source/drain trenches 126. Specifically, the CESL 136 is conformally formed on the sidewalls of the gate spacers 124, over the top surfaces of the source/drain features 134, as shown in FIGS. 13. The ILD layer 138 is then formed over the CESL 136 to fill a remaining space between (or inside) the CESL 136, between the gate spacers 124 and in the source/drain trenches 126.

The CESL 136 includes a material that is different than ILD layer 138. The CESL 136 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 138 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD 138 may be formed by PECVD (plasma enhanced CVD), FCVD (flowable CVD), or other suitable methods.

Subsequent to the deposition of the CESL 136 and the ILD layer 138, a CMP process and/or other planarization process is performed on the CESL 136 and the ILD layer 138 until the top surfaces of the dummy gate electrodes 122 and the gate spacers 124 are exposed. In some embodiments, portions of the dummy gate electrodes 122 are removed after the planarization process. In some embodiments, the ILD layer 138 is recessed to a level below the top surface of the dummy gate electrode 122, and then an ILD protection layer is formed over the ILD layer 138 to protect the ILD layer 138 from subsequent etching processes. As such, the ILD layer 138 is surrounded by the CESL 136 and the ILD protection layer. In some embodiments, the ILD protection layer includes a material that is the same as or similar to that in the CESL 136. In some other embodiments, the ILD protection layer includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, or other suitable methods.

Referring to FIG. 14A to 14C, portions of the dummy gate structures 118-2, the fins 112 (specifically, fins 112-2 and 112-3), the gate spacers 124, the inner spacers 130, and the substrate 102 are recessed or removed to form a trench 140. The trench 802 extends in the Y-direction, as shown in FIGS. 14A and 14C. The trench 140 may be formed by performing one or more lithography and etching processes to remove the portions of the dummy gate structures 118-2, the fins 112 (specifically, fins 112-2 and 112-3), the gate spacers 124, the inner spacers 130, and the substrate 102. In some embodiments, a single etchant may be used to remove the dummy gate structures 118-2, the fins 112 (specifically, fins 112-2 and 112-3), the gate spacers 124, the inner spacers 130, and the substrate 102, whereas in other embodiments, multiple etchants may be used to perform the etching processes.

As shown in FIGS. 14A and 14C, the dummy gate structure 118-2 is divided into dummy gate structures 118-2A and 118-2B by the trench 140 (may be collectively referred to as dummy gate structures 118 with dummy gate structures 118-1 and 118-3). Furthermore, the portions of the fins 112-2 and 112-3 and the substrate 102 thereunder are removed to form openings 140-1 and 140-2 in the trench 140, as shown in FIG. 14C. In some embodiments, the top surfaces of the isolation features 116 are exposed in the trench 140. Although a single trench (the trench 140) is shown in FIGS. 14A to 14C, it is understood that more trenches are formed to cut the dummy gate structures 118. In addition, although the trench 140 is formed across two fins 112-2 and 112-3 (i.e., the portions of the fins 112-2 and 112-3 are removed for the trench 140), it is noted that less or more fins may be partially removed to form smaller or larger trench 140.

Referring to FIG. 15A to 15C, a liner layer 142 and a dielectric structure 144 is formed in the trench 140. The liner layer 142 is conformally formed in the trench 140 and the dielectric structure 144 is formed over the liner layer 142 in the trench 140 (or the space in the liner layer 142 and the trench 140). More specifically, a material for the liner layer 142 is conformally formed in the trench 802 and over the dummy gate structures 118, the gate spacers 124, the CESL 136, and the ILD layer 138. Then, a material for the dielectric structure 144 is formed to fill the trench 140 (the space in the liner layer 142 and the trench 140) and over the material for the liner layer 142. Next, a planarization process (e.g., a CMP process) is performed on the materials for the liner layer 142 and the dielectric structure 144 until top surfaces of the dummy gate structures 118, the gate spacers 124, the CESL 136, and the ILD layer 138 are exposed, and the remaining materials for the liner layer 142 and the dielectric structure 144 in the trench 140 becomes the liner layer 142 and the dielectric structure 144. The materials for the liner layer 142 and the dielectric structure 144 is formed by a deposition process, such as CVD, PVD, ALD, HDPCVD, MOCVD, RPCVD, PECVD, LPCVD, ALCVD, APCVD, other suitable methods, or combinations thereof. The material for the liner layer 142 may be silicon oxide (SiO₂) and the material for the dielectric structure 144 may be silicon nitride (Si₃N₄). In other words, the liner layer 142 is made of silicon oxide (SiO₂) and the dielectric structure 144 is made of silicon nitride (Si₃N₄), such that the stress and the charge between the liner layer 142 and the dielectric structure 144 has less influence on resultant structure. In some embodiments, the liner layer 142 and the dielectric structure 144 may includes silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), or combinations thereof.

As shown in FIG. 15C, due to the openings 140-1 and 140-2 in the trench 140 discussed above, the dielectric structure 144 has extension portions 144ex deep into the substrate 102. In some embodiments, the dielectric structure 144 has a plug shape in the Y-Z cross-sectional view, as shown in FIG. 15C. As shown in FIGS. 15A and 15B, the liner layer 142 and the dielectric structure 144 are also formed between the gate spacers 124 in the X-direction. The liner layer 142 separate the dielectric structure 144 from the gate spacers 124. In other words, the liner layer is between the dielectric structure 144 and the gate spacers 124. Furthermore, in the X-Y cross-sectional view (the top view) shown in FIG. 15A, the dielectric structure 144 extends in the Y-direction and has a middle portion 144m and two end portions 144e on opposite sides of the middle portion 144m in the Y-direction. In the present embodiments, the dielectric structure 144 is formed and designed with the end portions 144e having a smaller width and the middle portion 144m having a larger width. More specifically, the width of the end portions 144e of the dielectric structure 144 in the X-direction is less than the width of the middle portion 144m of the dielectric structure 144 in the X-direction. In some embodiments, the width of the end portions 144e of the dielectric structure 144 in the X-direction is substantially level with a dimension of the dummy gate structures 118 in the X-direction, as shown in FIG. 15A. In some aspects, the dielectric structure 144 has a rolling pin shape in the X-Y cross-sectional view, as shown in FIG. 15A. Such end portions 144e of the dielectric structure 144 with width different form the width of the middle portion 144m of the dielectric structure 144 may be referred to as jog end portions. With such dielectric structure 144, the gate spacers 124 on opposite sides of the end portions 144e of the dielectric structure 144 can avoid being over etched or damaged during the formation of gate structure, the detail will be discussed below.

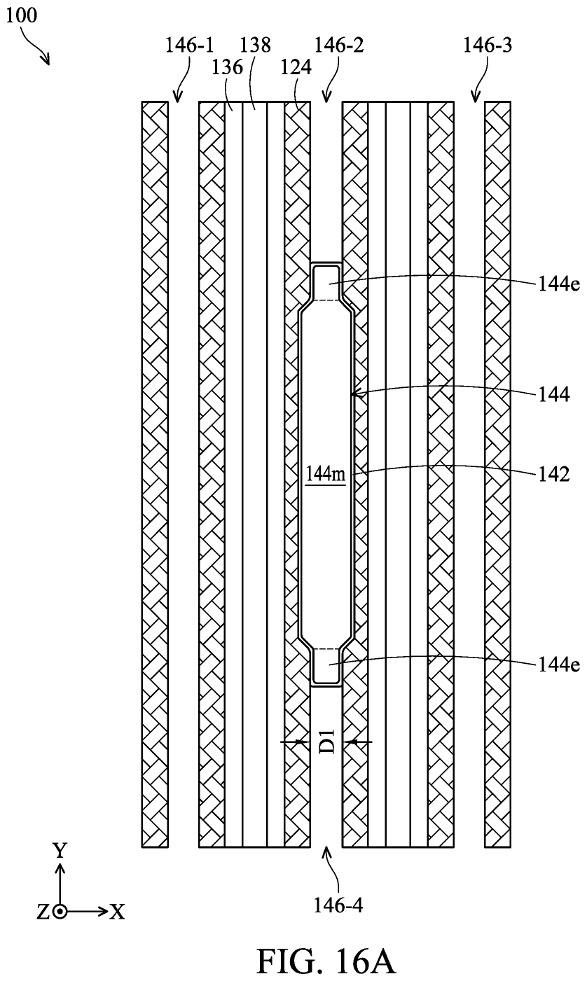

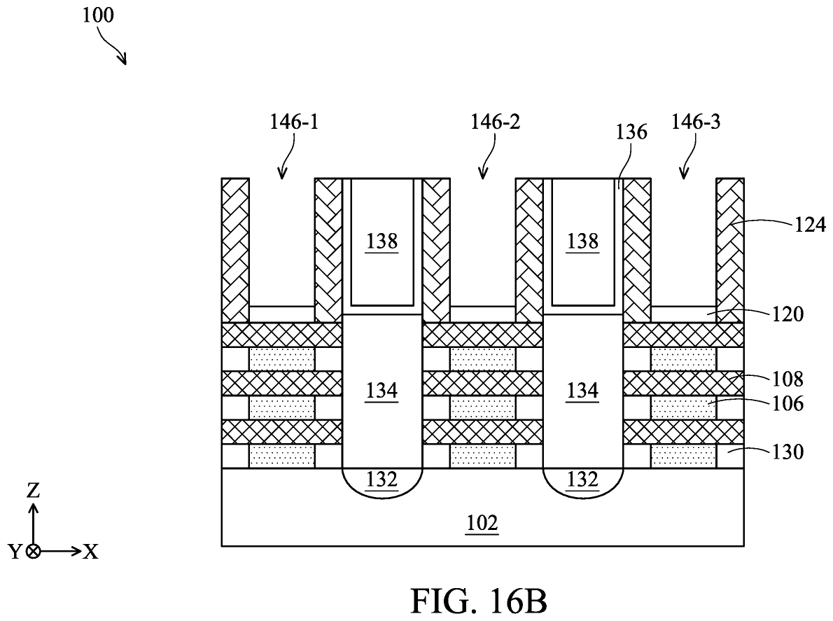

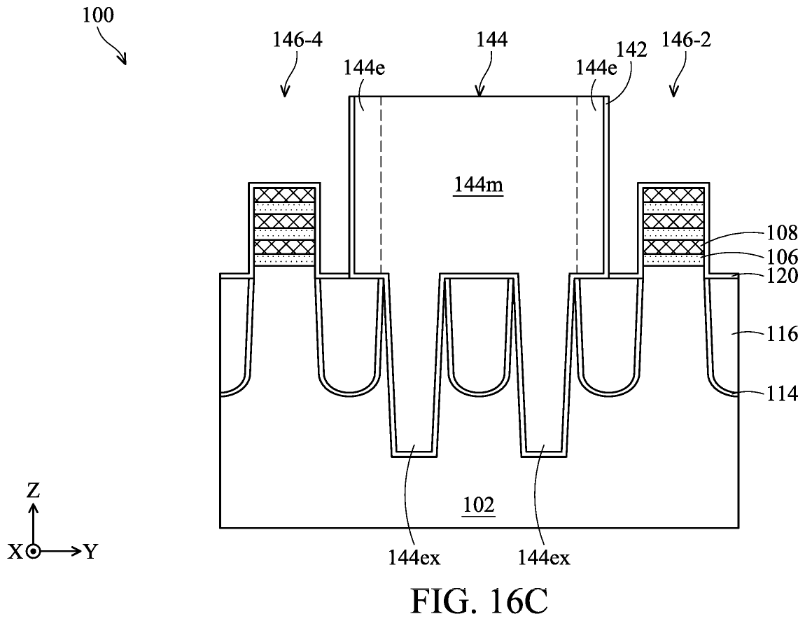

Referring to FIG. 16A to 16C, the dummy gate electrodes 122 of the dummy gate structures 118 are selectively removed through any suitable lithography and etching processes to form gate trenches 146 (including gate trenches 146-1 to 146-4). In some embodiments, the lithography process may include forming a photoresist layer (resist), exposing the resist to a pattern, performing a post-exposure bake process, and developing the resist to form a masking element, which exposes a region including the dummy gate structures 118. Then, the dummy gate electrodes 122 of the dummy gate structures 118 are selectively etched through the masking element. The gate spacers 124 may be used as the masking element or a part thereof. Etch selectivity may be achieved by selecting the appropriate etching chemicals, and the dummy gate electrode 122 may be removed without substantially affecting the dummy interfacial layers 120 of the dummy gate structures 118, the CESL 136, and the ILD layer 138. The removal of the dummy gate electrodes 122 of the dummy gate structures 118 creates the gate trenches 146-1 to 146-4, in which the gate trenches 146-1 to 146-4 expose the top surfaces of the dummy interfacial layers 120 of the dummy gate structures 118. Furthermore, the gate trenches 146-2 and 146-4 also expose the liner layer 142 on (the end portions 144e of) the dielectric structure 144 in the Y-direction, as shown in FIG. 16C.

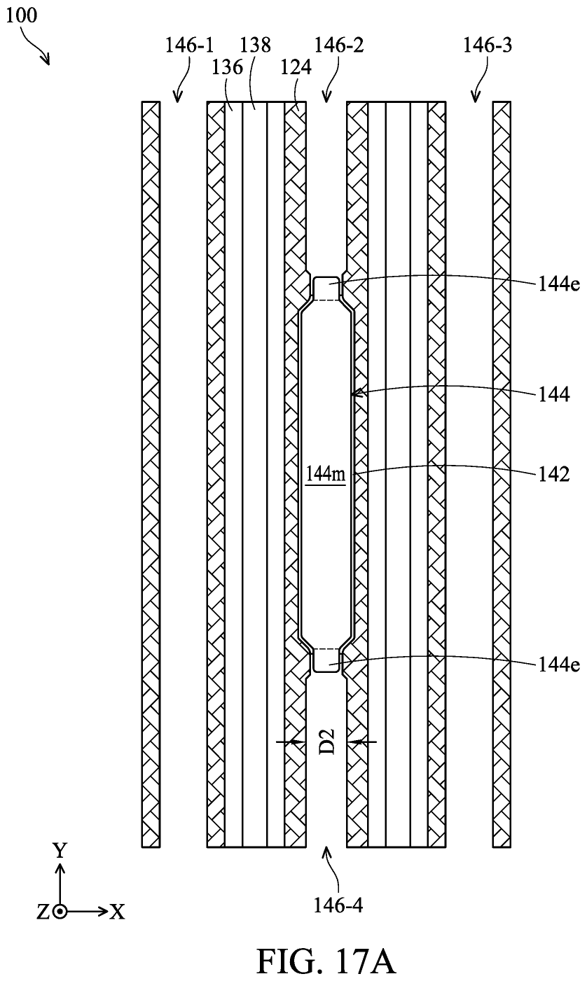

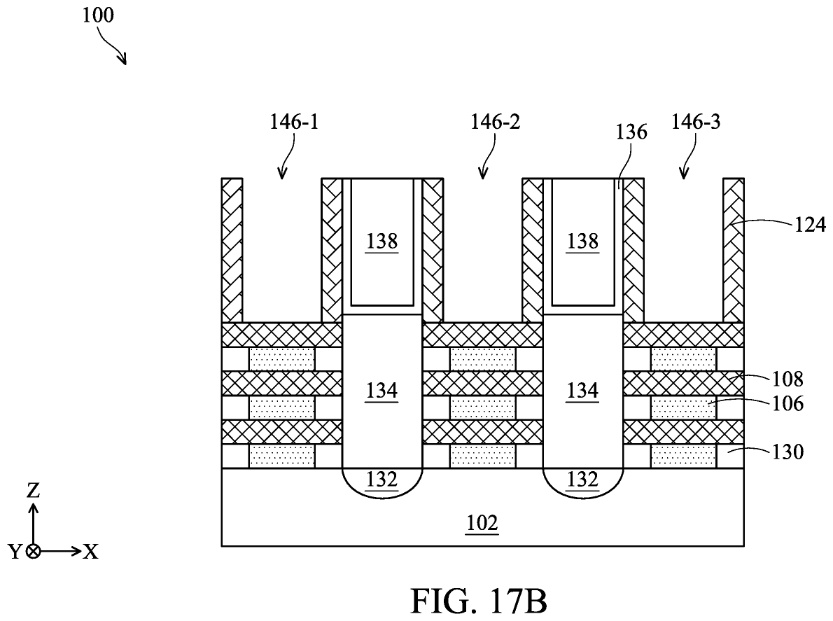

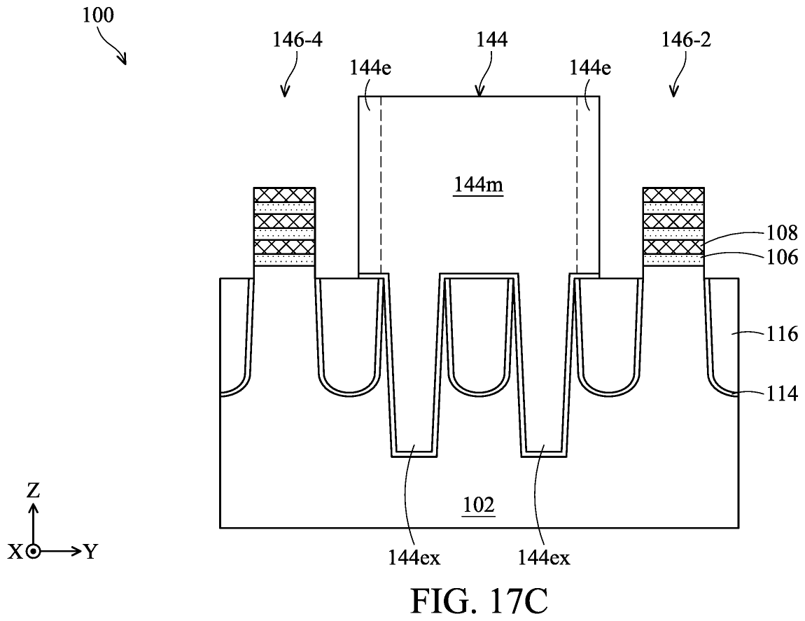

Referring to FIG. 17A to 17C, the dummy interfacial layers 120 of the dummy gate structures 118 are selectively removed through any suitable lithography and etching processes. More specifically, the dummy interfacial layers 120 are selectively removed by the selective etching process with minimal (or no) etching of semiconductor layers 108, the liner layer 114, the isolation features 116, the CESL 136, and the ILD layer 138. The selective etching process is a dry etching process, a wet etching process, other suitable etching process, or combinations thereof. Furthermore, portions of the gate spacers 124 are also removed during the removal of the dummy interfacial layers 120 of the dummy gate structures 118. As shown in FIG. 17A, the gate spacers 124 are partially removed, such that the distance D2 between the gate spacers 124 is less than the distance D1 between the gate spacers 124 shown in FIG. 16A. As shown in FIGS. 17A and 17C, the liner layer 142 on the end portions 144e of the dielectric structure 144 is also removed during the removal of the dummy interfacial layers 120 of the dummy gate structures 118. The sidewalls of the end portions 144e of the dielectric structure 144 are exposed in the gate trenches 146. In some embodiments, the end portions 144e of the dielectric structure 144 is partially removed, such that the length of the end portions 144e in the Y-direction shown in FIGS. 17A and 17C is less than the length of the end portions 144e in the Y-direction shown in FIGS. 16A and 16C.

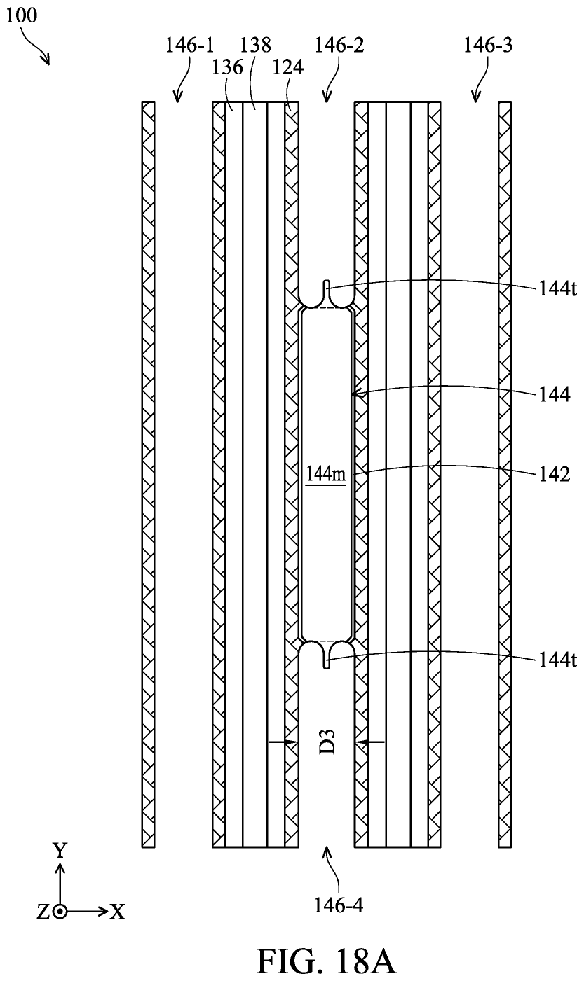

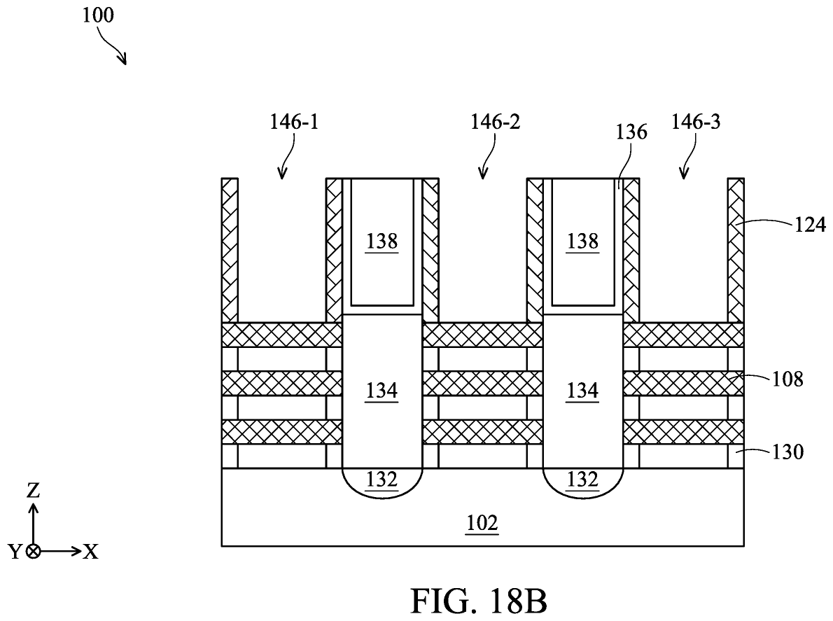

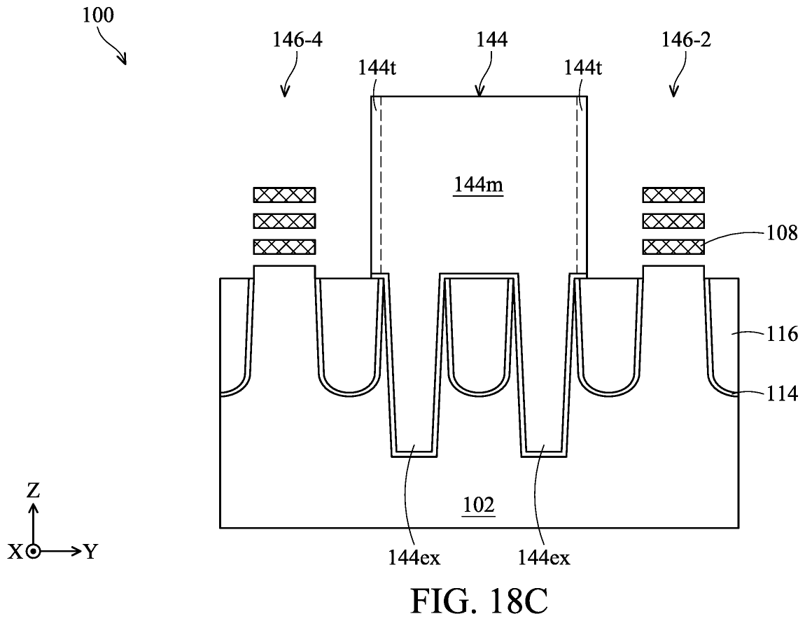

Referring to FIGS. 18A and 18B, the semiconductor layers 106 of the fins 112 are selectively removed through the gate trenches 146, using a wet or dry etching process for example, so that middle portions of the semiconductor layers 108 are exposed in the gate trenches 146 to form nanostructures stacked over each other, which serving as channels, channel layers, or channel members for resultant transistors. As such, the semiconductor layers 108 may be referred to as nanostructures. Specifically, the semiconductor layers 108 are stacked over each other in the Z-direction. Such a process may also be referred to as a release process, a channel release process, a wire release process, a nanowire release process, a nanosheet release process, a nanowire formation process, a nanosheet formation process, or a wire formation process.

In some embodiments, the removal of the semiconductor layers 106 causes the exposed semiconductor layers 108 to be spaced apart from each other in the vertical direction (e.g., in the Z-direction). The exposed semiconductor layers 108 extend longitudinally in the horizontal direction (e.g., in the X-direction). As shown in FIG. 18B, sidewalls of the inner spacers 130 are also exposed in the gate trenches 146. Furthermore, each of the semiconductor layers 108 connects one source/drain feature 134 to the other source/drain feature 134 (e.g., shown in FIG. 18B). In some embodiments, thicknesses of the semiconductor layers 108 exposed in the gate trenches 146 may be reduced during the removal of the semiconductor layers 106. In other embodiments, heights of the substrate 102 exposed in the gate trenches 146 may also be reduced during the removal of the semiconductor layers 106.

Furthermore, portions of the gate spacers 124 are also removed during the removal of the semiconductor layers 106. As shown in FIG. 18A, the gate spacers 124 are partially removed, such that the distance D3 between the gate spacers 124 is greater than the distance D2 between the gate spacers 124 shown in FIG. 18A. As discussed above, the width of the end portions 144e of the dielectric structure 144 in the X-direction is substantially level with a dimension of the dummy gate structures 118 in the X-direction. Therefore, portions of the gate spacers 124 facing the end portions 144e may be not over etched or damaged during the removal of the semiconductor layers 106. In some embodiments, the end portions 144e of the dielectric structure 144 is partially removed into tenon end portions 144t of the dielectric structure 144 (would match mortise end portions of gate structures, the detail will be discussed below), as shown in FIGS. 18A and 18C. Furthermore, the tenon end portions 144t of the dielectric structure 144 has a funnel shape in the X-Y cross-sectional view (the top view). The length of the tenon end portions 144t in the Y-direction shown in FIGS. 18A and 18C is less than the length of the end portions 144e in the Y-direction shown in FIGS. 17A and 17C. In some embodiments, as shown in FIG. 18B, the inner spacers 130 are also partially removed during the removal of the semiconductor layers 106, such that the width of the inner spacers 130 in the X-direction is reduced. As such, the gate trenches 146 are enlarged after the removal of the dummy interfacial layers 120 and the semiconductor layers 106. In addition, the gate trenches 146-2 and 146-4 are enlarged to have a shape match the tenon end portions 144t of the dielectric structure 144, in the X-Y cross-sectional view (the top view) shown in FIG. 18A.

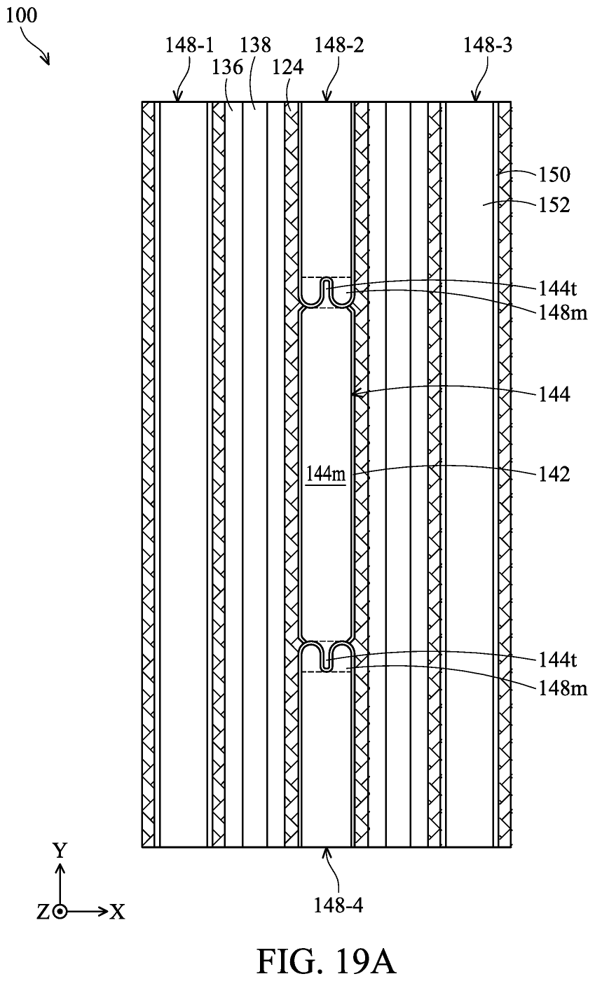

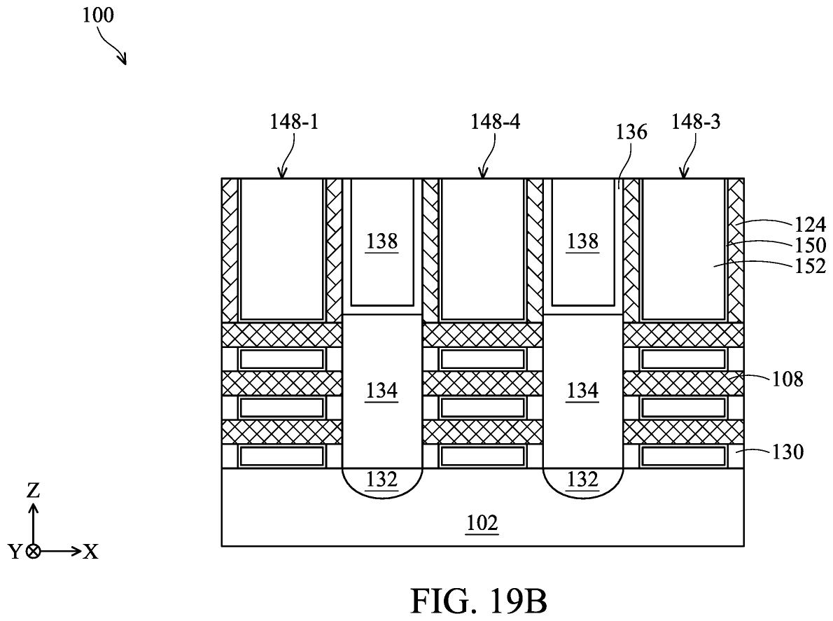

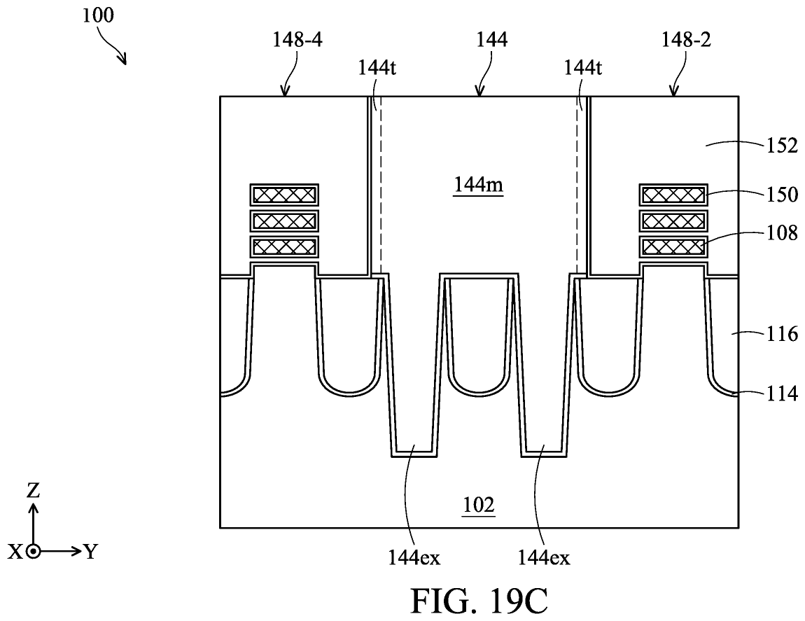

Referring to FIGS. 19A to 19C, gate structures 148 (including gate structures 148-1 to 148-4) are formed in the gate trenches 146 to wrap around the middle portions of the exposed semiconductor layers 108 (the nanostructures). As such, the gate structures 148 replace the dummy gate structures 118. In some embodiments, the gate structures 148 also extend in the Y-direction, as shown in FIGS. 19A and 19C. As shown in FIG. 19B, the source/drain features 134 are disposed on opposite sides of the gate structure 148-2 in the X-direction. The gate structures 148 each includes gate dielectric layer 150 and gate electrode 152 over the gate dielectric layer 150. In some embodiments, the gate dielectric layers 150 are formed to wrap around the semiconductor layers 108 in the gate trenches 143. Additionally, the gate dielectric layers 150 also formed on the sidewalls of the inner spacers 130, the gate spacers 124, and the dielectric structure 144, as shown in FIGS. 19A to 19C.

The gate dielectric layers 150 may include a dielectric material having a dielectric constant greater than a dielectric constant of SiO₂, which is approximately 3.9. For example, the gate dielectric layers 150 may include hafnium oxide (HfO₂), which has a dielectric constant in a range from about 18 to about 40. Alternatively, the gate dielectric layers 150 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The gate dielectric layers 150 may be formed by ALD, PVD, CVD, oxidation, and/or other suitable methods.

In some embodiments, the gate structures 148 each may further include interfacial layer formed to wrap around the exposed semiconductor layers 108 before the formation of the gate dielectric layers 150, so that the gate dielectric layers 150 are separated from semiconductor layers 108 by the interfacial layer. In some embodiments, the interfacial layer may include a dielectric material such as silicon oxide (SiO₂), HfSiO, or silicon oxynitride (SiON). The interfacial layer may be formed by chemical oxidation, thermal oxidation, ALD, CVD, and/or other suitable method.

The gate electrodes 152 are formed to fill the remaining spaces of the gate trenches 143, and over the gate dielectric layers 150 in such a way that the gate electrodes 152 wrap around the semiconductor layers 108, the gate dielectric layers 150, and the interfacial layers (if present). The gate electrodes 152 each may include a single layer or alternatively a multi-layer structure. In some embodiments, the gate electrodes 152 each may include a capping layer, a barrier layer, work function metal layers, and a fill material.

The capping layer may be formed adjacent to the gate dielectric layers 150 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The gate electrodes 152 may each has single or multiple work function metal materials. In some embodiments, the gate electrodes 152 may each has n-type work function metal layers for n-type GAA transistors and p-type work function metal layers for p-type GAA transistors. More specifically, the gate electrodes 152 may each has n-type work function metal layers between the source/drain features 134 with n-type dopant for n-type GAA transistors and p-type work function metal layers between the source/drain features 134 with p-type dopant for p-type GAA transistors, in accordance with some embodiments of the present disclosure.

In some embodiment, the n-type work function metal layer may be a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

In some embodiments, the p-type work function metal layer may be a material such as TiN, TaN, Ru, Mo, Al, WN, ZrSi₂, MoSi₂, TaSi₂, NiSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the P-type work function metal layer may be deposited using a deposition process such as ALD, CVD, or the like, although any suitable deposition process may be used.

Therefore, the workpiece 100 (or the semiconductor structure 100) with GAA transistors/devices are provided. As shown in FIG. 18A, due to the shape of the gate trenches 146-2 and 146-4 discussed, the gate structures 148-2 and 148-4 are formed to include a mortise end portion 148m. The dielectric structure 144 is in contact with the gate structures 148-2 and 148-4 in the Y-direction. More specifically, the tenon end portions 144t of the dielectric structure 144 match and are in contact with the mortise end portions 148m of the gate structures 148-2 and 148-4 in the Y-direction. In some embodiments, the mortise end portion 148m of the gate structures 148-2 and 148-4 are also in contact with the liner layer 142, as shown in FIGS. 19A and 19C. The tenon end portions of the dielectric structure 144 is separated from the gate spacers 124 by the mortise end portions 148m of the gate structures 148-2 and 148-4. As shown in FIG. 19A, the gate spacers 124 are on opposite sides of the gate structures 148-2 and 148-4 and the dielectric structure 144 in the X-direction. Furthermore, sidewalls of the gate spacers 124 facing the mortise end portion 148m of the gate structures 148-2 and 148-4 are aligned with sidewalls of the gate spacers 124 facing the dielectric structure 144 (more specifically, the middle portion 144m of the dielectric structure 144) in the Y-direction. In other words, the sidewalls of the gate spacers 124 in contact with the mortise end portions 148m of the gate structures 148-2 and 148-4 are aligned with the sidewalls of the gate spacers 124 in contact with the liner layer 142 in the Y-direction. As shown in FIG. 19A, each of the mortise end portions 148m of the gate structures 148-2 and 148-4 has rabbit ear portions sandwiching the tenon end portions 144t of the dielectric structure 144 in the X-Y cross-sectional view (the top view).

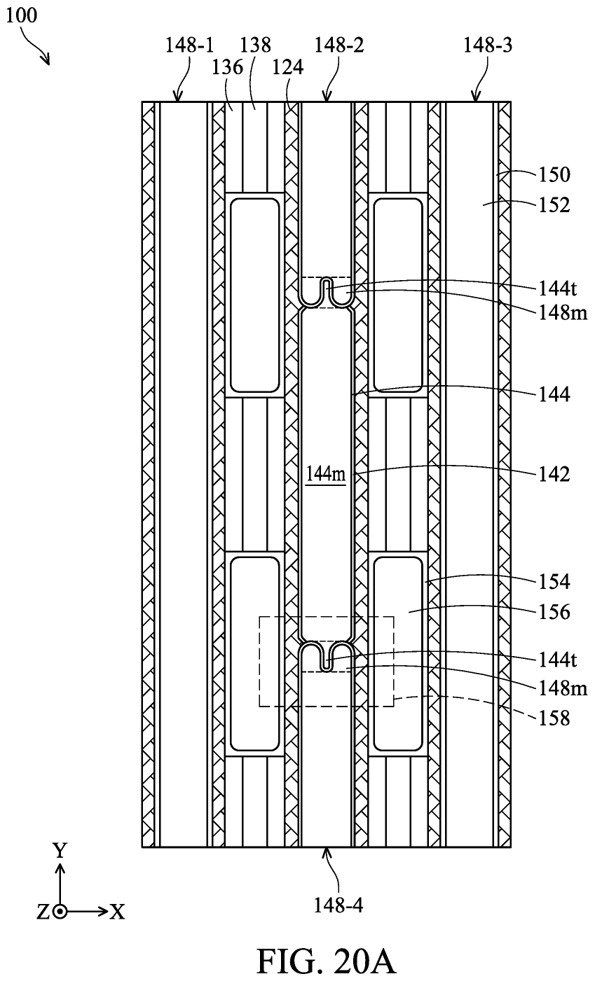

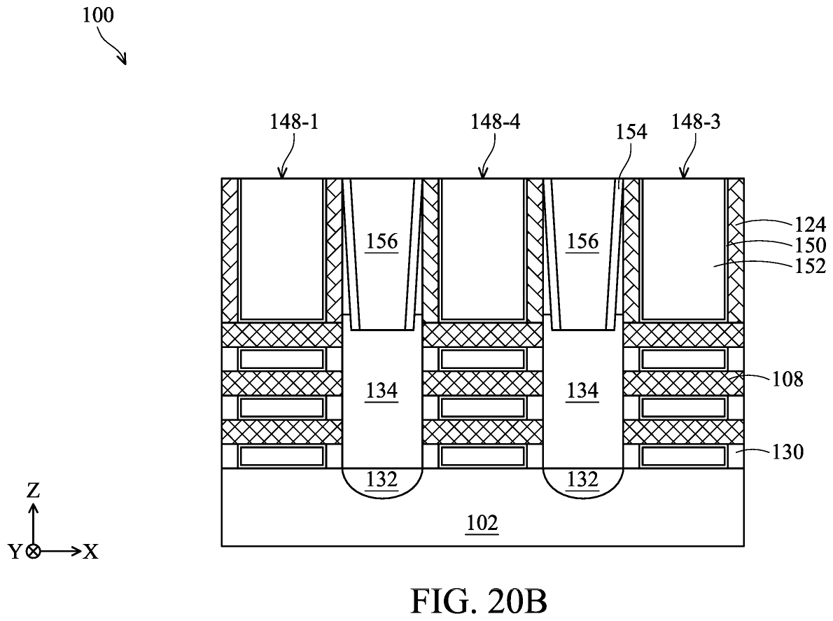

Referring to FIGS. 20A and 20B, source/drain contacts 156 are formed. More specifically, as shown in FIG. 20B, the source/drain contacts 156 are formed over the source/drain features 134, and passing through the CESL 136 and the ILD layer 138. Furthermore, the source/drain contacts 156 are formed on opposite sides of the gate structures 148 (e.g., the gate structures 148-2 and 148-4) and the dielectric structure 144, as shown in FIG. 20A. In some embodiments, portions of the source/drain features 134 are removed during the formation of the source/drain contact 156. The source/drain contacts 156 are electrically connected to (top surfaces of) the source/drain features 134. The conductive material of the source/drain contacts 156 may include Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 156 may include single conductive material layer or multiple conductive layers. In some embodiments, before the formation of the source/drain contacts 156, liner layers 154 including silicon nitride (Si₃N₄) are formed on sidewalls of the CESL 136. More specifically, the liner layers 154 are formed to laterally wrap around the source/drain contacts 156.

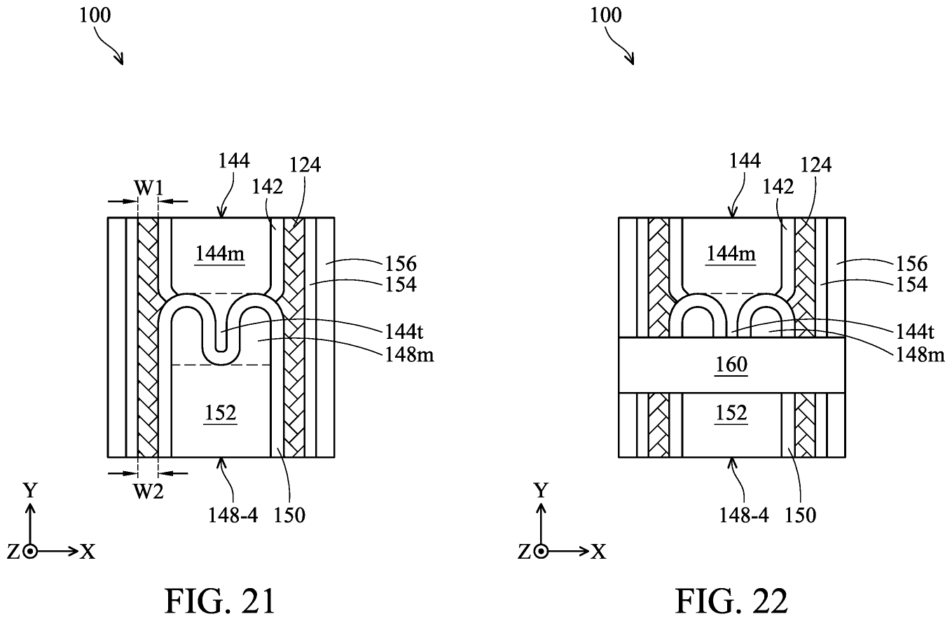

FIG. 21 is a partial enlarged top view of the workpiece 100 at the fabrication stage in a dashed box 158 of FIG. 20A, in accordance with some embodiments of the present disclosure. As discussed above, the shape of the dielectric structure 144 shown in FIG. 15A can prevent the gate spacers 124 (facing the end portions 144e/the tenon end portions 144t) from being over etched or damaged during the formation of the gate structures 148 shown in FIGS. 17A to 17C and 18A to 18C. Therefore, as shown in FIG. 21, the sidewalls of the gate spacers 124 facing the mortise end portion 148m of the gate structures 148-2 and 148-4 are aligned with the sidewalls of the gate spacers 124 facing the dielectric structure 144 (more specifically, the middle portion 144m of the dielectric structure 144) in the Y-direction, as discussed above. As such, the width W1 of the gate spacers 124 between the liner layers 154 and the liner layer (i.e., the gate spacers 124 on opposite sides of the dielectric structure 144) in the X-direction is substantially level with the width W1 of the gate spacers 124 between the liner layers 154 and the gate structures 148 (e.g., the gate structure 148-4) (i.e., the gate spacers 124 on opposite sides of the gate structures 148) in the X-direction, as shown in FIG. 21. In some embodiments, each of the width W1 and W2 is in a range from about 2 nm to about 3 nm. The width of the middle portion 144m of the dielectric structure 144 in the X-direction is greater than about 15 nm and the width of the tenon end portions 144t of the dielectric structure 144 in the X-direction is less than about 15 nm. Furthermore, the width of the tenon end portions 144t of the dielectric structure 144 in the X-direction is in a range from about 2 nm to about 10 nm.

Therefore, due to the gate spacers 124 facing the end portions 144e/the tenon end portions 144t of the dielectric structure 144 are not over etched or damaged, as discussed above, the mortise end portions 148m of the gate structures 148 (e.g., the gate structures 148-2 and 148-4) would not be formed too close to the source/drain contacts 156, such that the parasitic capacitance between the gate structures 148 and the source/drain contacts 156 is reduced, thereby improving the performance of the GAA transistors.

FIG. 22 is a partial enlarged top view of the workpiece at the fabrication stage in the dashed box of FIG. 20A, in accordance with some alternative embodiments of the present disclosure. In some embodiments, a dielectric structure 144 is formed to separate the mortise end portions 148m from the gate structures 148. For examples, as shown in FIG. 22, the dielectric structure 144 is formed to separate the mortise end portion 148m from the gate structure 148-4. The dielectric structure 144 is formed in contact with the mortise end portions 148m (including the gate dielectric layers 150 and the gate electrodes 152). Therefore, the influence of the mortise end portions 148m on the electrical characteristics of the resultant GAA transistors can be reduced. The dielectric structure 144 may includes silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), or combinations thereof.

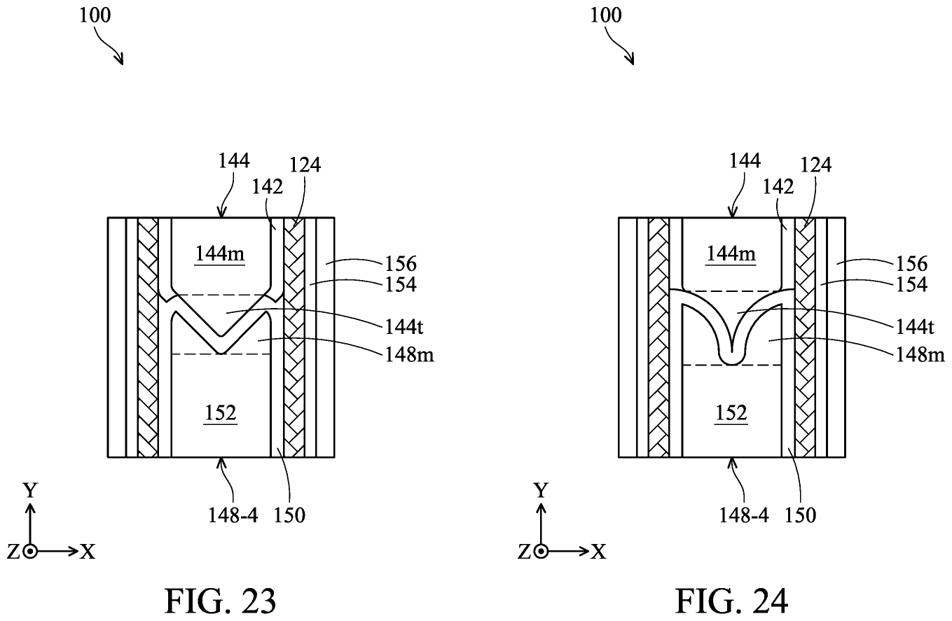

FIGS. 23 to 25 are partial enlarged top views of the workpiece 100 at the fabrication stage in the dashed box 158 of FIG. 20A, in accordance with some alternative embodiments of the present disclosure. The structure shown in FIGS. 23 to 25 are similar to the structure shown in FIG. 21 discussed above, except that the tenon end portions 144t of the dielectric structure 144 and the mortise end portions 148m of the gate structures 148 shown in FIGS. 23 to 25 have different shapes from that shown in FIG. 21. Referring back to FIG. 21, as discussed above, the tenon end portions 144t of the dielectric structure 144 has a funnel shape in the X-Y cross-sectional view (the top view) and the mortise end portions 148m of the gate structures 148 (e.g., the gate structures 148-2 and 148-4) has rabbit ear portions sandwiching the tenon end portions 144t of the dielectric structure 144 in the X-Y cross-sectional view (the top view).

As shown in FIG. 23, the tenon end portions 144t of the dielectric structure 144 has a triangle shape in the X-Y cross-sectional view (the top view) and the mortise end portions 148m of the gate structures 148 has triangle shapes (more specifically, the right triangle shapes) sandwiching the tenon end portions 144t of the dielectric structure 144 in the X-Y cross-sectional view (the top view).

As shown in FIG. 24, the tenon end portions 144t of the dielectric structure 144 has a spike shape in the X-Y cross-sectional view (the top view) and the mortise end portions 148m of the gate structures 148 has quarter round shapes sandwiching the tenon end portions 144t of the dielectric structure 144 in the X-Y cross-sectional view (the top view).

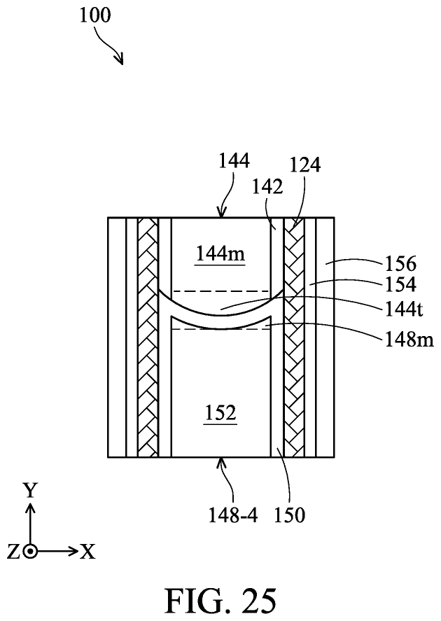

As shown in FIG. 25, the tenon end portions 144t of the dielectric structure 144 has a semicircle shape (with a convex surface) in the X-Y cross-sectional view (the top view) and each of the mortise end portions 148m of the gate structures 148 has a concave surface in contact with the tenon end portions 144t of the dielectric structure 144 in the X-Y cross-sectional view (the top view).

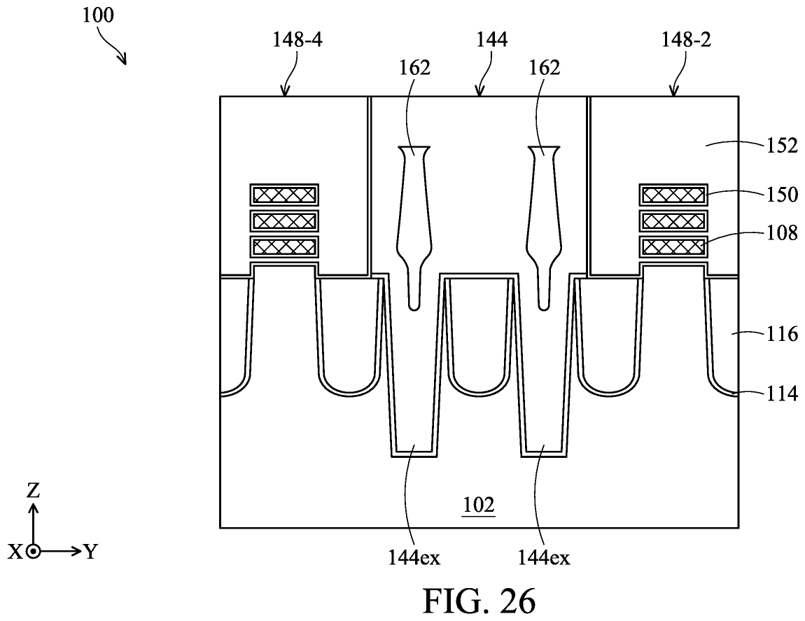

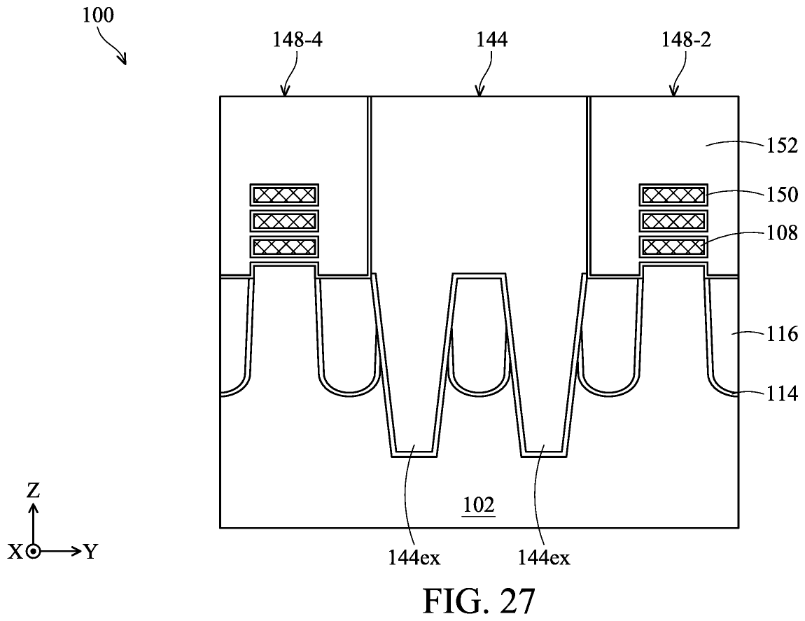

FIGS. 26 and 27 are Y-Z cross-sectional views of the workpiece 100 at the fabrication stage along the line B-B′ of FIG. 7, in accordance with some alternative embodiments of the present disclosure. The structure shown in FIGS. 26 and 27 are similar to the structure shown in FIG. 19C discussed above, except that the dielectric structure 144 shown in FIGS. 26 and 27 have different shapes from that shown in FIG. 19C. As shown in FIG. 26, the dielectric structure 144 further has voids 162 with air. The voids 162 are over the extension portions 144ex deep into the substrate 102 discussed above. Therefore, the parasitic capacitance of the GAA transistors can be reduced. As shown FIG. 27, the liner layer 114 and the isolation features 116 are partially removed during the formation of the dielectric structure 144. Therefore, the dielectric structure 144 is formed with larger extension portions 144ex than that shown in FIG. 19C. Furthermore, sidewalls of the isolation features 116 in such embodiment are in contact with the liner layers 142 in the Y-direction, as shown in FIG. 27. The dielectric structure 144 with such larger extension portions 144ex has larger electrically isolation.

The embodiments disclosed herein relate to semiconductor structures and their manufacturing methods, and more particularly to methods and semiconductor structures including GAA transistors with a dielectric structure with tenon end portions/jog end portions, such that gate spacers would not be over etched (or damaged) during the formation of the gate structure, thereby the gate structure would not be formed too close to the source/drain contacts. Furthermore, the present embodiments provide one or more of the following advantages. The parasitic capacitance between the gate structures and the source/drain contacts is reduced. Therefore, the performance of the GAA transistor is improved.

Thus, one of the embodiments of the present disclosure describes a semiconductor structure that includes a substrate, nanostructures, source/drain features, a gate structure, and a dielectric structure. The nanostructures are over the substrate and spaced apart from each other in a Z-direction. The source/drain features are electrically connected to and on opposite sides of the nanostructures in an X-direction.

The gate structure extends in a Y-direction and wraps around the nanostructures. The dielectric structure extends in the Y-direction and is in contact with the gate structure in the Y-direction. The gate structure includes a mortise end portion. The dielectric structure includes a tenon end portion matching the mortise end portion of the gate structure.

In some embodiments, the semiconductor structure further includes gate spacers on the opposite sides of the gate structure in the X-direction. The dielectric structure is between the gate spacers in the X-direction.

In some embodiments, the tenon end portion of the dielectric structure is separated from the gate spacers by the mortise end portion of the gate structure.

In some embodiments, sidewalls of the gate spacers facing the mortise end portion of the gate structure are aligned with sidewalls of the gate spacers facing the dielectric structure in the Y-direction.

In some embodiments, the semiconductor structure further includes a liner layer separating the dielectric structure from the gate spacers.

In some embodiments, the tenon end portion of the dielectric structure has a funnel shape in a top view.

In some embodiments, the tenon end portion of the dielectric structure has a spike shape in a top view.

In some embodiments, the tenon end portion of the dielectric structure has a triangle shape in a top view.

In some embodiments, the tenon end portion of the dielectric structure has a semicircle shape in a top view.

In some embodiments, the dielectric structure has a void.

In another of the embodiments, discussed is a semiconductor structure including a substrate, nanostructures, a gate structure, source/drain features, a dielectric structure, and gate spacers. The nanostructures are over the substrate and spaced apart from each other in a Z-direction. The gate structure extends in a Y-direction and wraps around the nanostructures. The source/drain features are on opposite sides of the gate structure in an X-direction and attached to the nanostructures in the X-direction. The a dielectric structure aligned with the gate structure in the Y-direction. The gate spacers are on opposite sides of the gate structure and the dielectric structure in the X-direction. The gate structure includes a mortise end portion. The dielectric structure includes a tenon end portion in contact with the mortise end portion of the gate structure.

In some embodiments, the semiconductor structure further includes a liner layer between the dielectric structure and the gate spacers. The mortise end portion of the gate structure is in contact with the liner layer.

In some embodiments, sidewalls of the gate spacers in contact with the mortise end portion of the gate structure are aligned with sidewalls of the gate spacers in contact with the liner layer in the Y-direction.

In some embodiments, the mortise end portion of the gate structure has rabbit ear portions sandwiching the tenon end portion of the dielectric structure in a top view.

In some embodiments, the mortise end portion of the gate structure has triangle shapes sandwiching the tenon end portion of the dielectric structure in a top view.

In some embodiments, the mortise end portion of the gate structure has quarter round shapes sandwiching the tenon end portion of the dielectric structure in a top view.

In some embodiments, the mortise end portion of the gate structure has a concave surface in contact with the tenon end portion of the dielectric structure in a top view.

In yet another of the embodiments, discussed is a method for manufacturing a semiconductor structure that includes forming fins over a substrate. The fins include first semiconductor layers and second semiconductor layers alternating stacked in a Z-direction. The method further includes forming a dummy gate structure extending in a Y-direction and over the fins, forming source/drain features in the fin and on opposite sides of the dummy gate structures in an X-direction, removing portions of the dummy gate structure and the fins to form a trench, forming a dielectric structure in the trench, removing the dummy gate structure, the first semiconductor layers, and portions of the dielectric structure to form a gate trench, and forming a gate structure in the gate trench to wrap around the second semiconductor layers. The dielectric structure includes a tenon end portion. The gate structure includes a mortise end portion matching the tenon end portion of the dielectric structure.

In some embodiments, the method further includes conformally forming a liner layer in the trench, forming the dielectric structure over the liner layer in the trench, and removing a portion of the liner layer to form the gate trench.

In some embodiments, the method further includes forming gate spacers on opposite sides of the dummy gate structure, removing portions of the gate spacers to form the trench, and forming the dielectric structure between the gate spacers. A width of end portions of the dielectric structure is less than a width of a middle portion of the dielectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
nanostructures over the substrate and spaced apart from each other in a Z-direction;
source/drain features electrically connected to and on opposite sides of the nanostructures in an X-direction;
a gate structure extending in a Y-direction and wrapping around the nanostructures, wherein the gate structure comprises a mortise end portion; and
a dielectric structure extending in the Y-direction and in contact with the gate structure in the Y-direction, wherein the dielectric structure comprises a tenon end portion matching the mortise end portion of the gate structure.

2. The semiconductor structure of claim 1, further comprising:
gate spacers on the opposite sides of the gate structure in the X-direction, wherein the dielectric structure is between the gate spacers in the X-direction.

3. The semiconductor structure of claim 2, wherein the tenon end portion of the dielectric structure is separated from the gate spacers by the mortise end portion of the gate structure.

4. The semiconductor structure of claim 2, wherein sidewalls of the gate spacers facing the mortise end portion of the gate structure are aligned with sidewalls of the gate spacers facing the dielectric structure in the Y-direction.

5. The semiconductor structure of claim 2, further comprising:
a liner layer separating the dielectric structure from the gate spacers.

6. The semiconductor structure of claim 1, wherein the tenon end portion of the dielectric structure has a funnel shape in a top view.

7. The semiconductor structure of claim 1, wherein the tenon end portion of the dielectric structure has a spike shape in a top view.

8. The semiconductor structure of claim 1, wherein the tenon end portion of the dielectric structure has a triangle shape in a top view.

9. The semiconductor structure of claim 1, wherein the tenon end portion of the dielectric structure has a semicircle shape in a top view.

10. The semiconductor structure of claim 1, wherein the dielectric structure has a void.

11. A semiconductor structure, comprising:
a substrate;
nanostructures over the substrate and spaced apart from each other in a Z-direction;
a gate structure extending in a Y-direction and wrapping around the nanostructures, wherein the gate structure comprises a mortise end portion;
source/drain features on opposite sides of the gate structure in an X-direction and attached to the nanostructures in the X-direction;
a dielectric structure aligned with the gate structure in the Y-direction, wherein the dielectric structure comprises a tenon end portion in contact with the mortise end portion of the gate structure; and
gate spacers on opposite sides of the gate structure and the dielectric structure in the X-direction.

12. The semiconductor structure of claim 11, further comprising:
a liner layer between the dielectric structure and the gate spacers, wherein the mortise end portion of the gate structure is in contact with the liner layer.

13. The semiconductor structure of claim 12, wherein sidewalls of the gate spacers in contact with the mortise end portion of the gate structure are aligned with sidewalls of the gate spacers in contact with the liner layer in the Y-direction.

14. The semiconductor structure of claim 1, wherein the mortise end portion of the gate structure has rabbit ear portions sandwiching the tenon end portion of the dielectric structure in a top view.

15. The semiconductor structure of claim 11, wherein the mortise end portion of the gate structure has triangle shapes sandwiching the tenon end portion of the dielectric structure in a top view.

16. The semiconductor structure of claim 11, wherein the mortise end portion of the gate structure has quarter round shapes sandwiching the tenon end portion of the dielectric structure in a top view.

17. The semiconductor structure of claim 11, wherein the mortise end portion of the gate structure has a concave surface in contact with the tenon end portion of the dielectric structure in a top view.

18. A method for manufacturing a semiconductor structure, comprising:
forming fins over a substrate, wherein each of the fins comprises first semiconductor layers and second semiconductor layers alternating stacked in a Z-direction;
forming a dummy gate structure extending in a Y-direction and over the fins;
forming source/drain features in the fin and on opposite sides of the dummy gate structures in an X-direction;
removing portions of the dummy gate structure and the fins to form a trench;
forming a dielectric structure in the trench;
removing the dummy gate structure, the first semiconductor layers, and portions of the dielectric structure to form a gate trench, wherein the dielectric structure comprises a tenon end portion; and
forming a gate structure in the gate trench to wrap around the second semiconductor layers, wherein the gate structure comprises a mortise end portion matching the tenon end portion of the dielectric structure.

19. The method of claim 18, further comprising:
conformally forming a liner layer in the trench;
forming the dielectric structure over the liner layer in the trench; and
removing a portion of the liner layer to form the gate trench.

20. The method of claim 18, further comprising:
forming gate spacers on opposite sides of the dummy gate structure;
removing portions of the gate spacers to form the trench; and
forming the dielectric structure between the gate spacers, wherein a width of end portions of the dielectric structure is less than a width of a middle portion of the dielectric structure.
